(19) United States
(12) Patent Application Publication
(10) Pub. No.: US 2025/0239302 A1
(43) Pub. Date: Jul. 24, 2025

(54) SEMICONDUCTOR INTEGRATED CIRCUIT AND ELECTRONIC DEVICE

(71) Applicant: SONY SEMICONDUCTOR SOLUTIONS CORPORATION, KANAGAWA (JP)

(72) Inventors: TADAAKI TANIMOTO, KANAGAWA (JP); KEIZO HIRAGA, KANAGAWA (JP); TAKESHI EGUCHI, KANAGAWA (JP); KAZUHIRO BESSHO, KANAGAWA (JP)

(21) Appl. No.: 18/852,709

(22) PCT Filed: Feb. 9, 2023
(86) PCT No.: PCT/JP2023/004314

§ 371 Date: Sep. 30, 2024

(30) Foreign Application Priority Data
Apr. 8, 2022 (JP) 2022-064196

(51) Int. Cl. G11C 14/00; G11C 5/14

(52) U.S. Cl. CPC G11C 14/0081; G11C 5/141

(57) ABSTRACT

To reduce power consumption in a semiconductor integrated circuit that holds configuration data. The semiconductor integrated circuit includes a long-term holding memory and a short-term holding memory. Among these memories in the semiconductor integrated circuit, the short-term holding memory has a data holding time shorter than a predetermined time and holds predetermined configuration data. Furthermore, the long-term holding memory in the semiconductor integrated circuit has a data holding time being the predetermined time and holds a specific data indicating whether or not a power supply voltage is recovered after dropping to a value lower than a constant voltage.

### TECHNICAL FIELD

The present technology relates to a semiconductor integrated circuit. Specifically, the present technology relates to a semiconductor integrated circuit that holds configuration data, and an electronic device.

### BACKGROUND ART

Conventionally, a field-programmable gate array (FPGA) is used in some cases as a semiconductor integrated circuit in a case where only a small amount of semiconductor integrated circuits is manufactured or in a case where a prototype thereof is manufactured. In the FPGA, a circuit configuration can be changed by rewriting configuration data including wire connection information of logical blocks and connection information of switches. For example, an FPGA using a magnetoresistive random access memory (MRAM) as a memory for storing the configuration data has been proposed (see, for example, Non-Patent Document 1).

### CITATION LIST

### Non-Patent Document

Non-Patent Document 1: W. Zhao, et al., Evaluation of a Non-Volatile FPGA based on MRAM technology, 2006 IEEE International Conference on IC Design and Technology.

### SUMMARY OF THE INVENTION

### Problems to be Solved by the Invention

In the above-described conventional technique, the MRAM is used instead of a static random access memory (SRAM) to prevent the configuration data from being lost when the power supply is shut off. However, in the semiconductor integrated circuit (FPGA) described above, there is a problem that power consumption increases at the time when the configuration data is written in the memory.

The present technology has been made in view of such a situation, and an object thereof is to reduce the power consumption in a semiconductor integrated circuit that holds configuration data in a memory.

### Solutions to Problems

The present technology has been made to solve the above-described problems, and a first aspect of the present technology is a semiconductor integrated circuit including: a short-term holding memory that has a data holding time shorter than a predetermined time and holds predetermined configuration data; and a long-term holding memory that has a data holding time being the predetermined time and holds specific data indicating whether or not a power supply voltage is recovered after dropping to a value lower than a constant voltage. This brings about an effect of reducing the power consumption of the semiconductor integrated circuit.

Furthermore, in the first aspect, the short-term holding memory is one of a magnetoresistive random access memory (MRAM) and a non-volatile static random access memory (SRAM), and the long-term holding memory may also be one of the MRAM and the SRAM. This brings about an effect of reducing the power consumption of a circuit using the MRAM or the non-volatile SRAM.

Furthermore, in the first aspect, each of the short-term holding memory and the long-term holding memory may include a memory cell disposed at an intersection of a bit line and a word line. This brings about an effect of reducing a mounting area.

Furthermore, in the first aspect, there may be further provided a check circuit that determines whether or not at least a part of the configuration data is lost and outputs a determination result. This brings about an effect that a time required for reactivation is shortened.

Furthermore, in the first aspect, the short-term holding memory may include a plurality of memory cells that holds the same value, and the check circuit may determine whether or not all the held values of the plurality of memory cells coincide with each other. This brings about an effect that the presence or absence of data loss is determined.

Furthermore, in the first aspect, the short-term holding memory may include a plurality of first memory cells that holds a first logical value and a plurality of second memory cells that holds a second logical value different from the first logical value, and the check circuit may determine whether or not all the held values of the plurality of first memory cells coincide with each other and all the held values of the plurality of second memory cells coincide with each other. This brings about an effect that the presence or absence of loss is determined for both the first logical value and the second logical value.

Furthermore, in the first aspect, there may be further provided a power supply shutoff recovery control unit that transits to: a write state in which the specific data having a value different from an initial value is held in the long-term holding memory in a case where the power supply voltage drops to a value lower than the constant voltage; a read state in which the specific data is read from the long-term holding memory in a case where the power supply voltage recovers to a value higher than the constant voltage; a check state in which the determination result is acquired in a case where the specific data that is read is not the initial value; and a reconfiguration state in which predetermined initial configuration data is held in the short-term holding memory as new configuration data in a case where at least a part of the configuration data is lost. This brings about an effect that reconfiguration is performed when data is lost.

Furthermore, in the first aspect, in a case where at least a part of the configuration data is lost, the power supply shutoff recovery control unit may cause the short-term holding memory to hold the initial configuration data read from a read only memory as new configuration data. This brings about an effect that the initial configuration data does not need to be held in the long-term holding memory.

Furthermore, in the first aspect, the long-term holding memory may further hold the initial configuration data, and the power supply shutoff recovery control unit may cause the short-term holding memory to hold the initial configuration data read from the long-term holding memory as new configuration data in a case where at least a part of the configuration data is lost. This brings about an effect that the read only memory becomes unnecessary.

Furthermore, in the first aspect, there may be further provided a check circuit that determines whether or not at least a part of the configuration data is lost and outputs a determination result, and an auxiliary power supply unit that supplies a predetermined auxiliary voltage when the power supply voltage is shut off. This brings about an effect that the auxiliary voltage is supplied when the power supply is shut off.

Furthermore, in the first aspect, the auxiliary power supply unit may include a diode and a capacitive element connected in series to the power supply voltage. This brings about an effect that the voltage of the connection node between the diode and the capacitive element is supplied.

Furthermore, in the first aspect, the auxiliary power supply unit may further include a primary battery that supplies the auxiliary voltage. This brings about an effect that the auxiliary voltage is supplied over a relatively long time.

Furthermore, in the first aspect, the auxiliary power supply unit may further include an energy harvester that performs energy harvesting. This brings about an effect that the power consumption of the auxiliary power supply unit is reduced. Furthermore, in the first aspect, the auxiliary power supply unit may further include a secondary battery that is charged with power from the energy harvester and is discharged when the power supply voltage is shut off. This brings about an effect that the auxiliary voltage is supplied over a relatively long time.

Furthermore, in the first aspect, there may be further provided a resonance circuit that generates a transient voltage that fluctuates with a lapse of time when the auxiliary voltage is supplied, and the check circuit may compare an absolute value of the transient voltage with a predetermined reference voltage and output a result of the comparison as the determination result. This brings about an effect that the logical operation becomes unnecessary at the time of determining the presence or absence of data loss.

Furthermore, in the first aspect, there may be further provided a real time clock that generates predetermined time information, and the check circuit may cause the long-term holding memory to hold time information when the power supply voltage is shut off, and determine whether or not a difference between a time indicated by the held time information and a time indicated by newly generated time information exceeds a predetermined threshold when the power supply voltage is recovered. This brings about an effect that the logical operation for determining the presence or absence of data loss becomes unnecessary.

Furthermore, in the first aspect, the short-term holding memory may include first and second short-term holding memories having different data holding times. This brings about an effect that the number of memory cells to be checked is reduced by checking only the memory cell having different data holding times.

Furthermore, in the first aspect, the semiconductor integrated circuit may be a field-programmable gate array (FPGA), the configuration data may include wire connection information of a logical block and connection information of a switch block, the short-term holding memory may be disposed in the logical block and the switch block, and the long-term holding memory may be disposed in the logical block. This brings about an effect of reducing the power consumption of the FPGA.

Furthermore, in the first aspect, the semiconductor integrated circuit may be a large scale integration (LSI), and the short-term holding memory may be disposed in a predetermined register. This brings about an effect that the power consumption of the LSI is reduced as compared with the case of using the long-term holding memory.

Furthermore, a second aspect of the present technology is an electronic device including: a semiconductor integrated circuit including a short-term holding memory that has a data holding time shorter than a predetermined time and holds predetermined configuration data and a long-term holding memory that has a data holding time longer than the predetermined time and holds specific data indicating whether or not a power supply voltage is recovered after dropping to a value lower than a constant voltage; and a power supply monitoring circuit that supplies a predetermined detection signal to the semiconductor integrated circuit in a case where it is detected that the power supply voltage is dropped to a value lower than the constant voltage. This brings about an effect of reducing the power consumption of the electronic device.

Furthermore, in the second aspect, there may be further provided a read only memory that holds initial configuration data; and a configuration controller that reads the initial configuration data from the read only memory and supplies the initial configuration data to the semiconductor integrated circuit. This brings about an effect that the initial configuration data does not need to be held in the long-term holding memory.

### BRIEF DESCRIPTION OF DRAWINGS

FIG. 1 is a block diagram illustrating a configuration example of an electronic device according to a first embodiment of the present technology.

FIG. 2 is a circuit diagram illustrating a configuration example of a power supply monitoring circuit according to the first embodiment of the present technology.

FIG. 3 is a circuit diagram illustrating a configuration example of a logical configuration unit according to the first embodiment of the present technology.

FIG. 4 is a circuit diagram illustrating a configuration example of a switch block according to the first embodiment of the present technology.

FIG. 5 is a circuit diagram illustrating a configuration example of a memory cell according to the first embodiment of the present technology.

FIG. 6 is a circuit diagram illustrating another example of the memory cell according to the first embodiment of the present technology.

FIG. 7 is a circuit diagram illustrating a configuration example of a switch circuit according to the first embodiment of the present technology.

FIG. 8 is a block diagram illustrating a configuration example of a logical block according to the first embodiment of the present technology.

FIG. 9 is a circuit diagram illustrating a configuration example of a check circuit according to the first embodiment of the present technology.

FIG. 10 is a circuit diagram illustrating another example of the check circuit according to the first embodiment of the present technology.

FIG. 11 is a circuit diagram illustrating a configuration example of the check circuit with a different logic gate according to the first embodiment of the present technology.

FIG. 12 is an example of a state transition diagram of a power supply shutoff recovery control unit according to the first embodiment of the present technology.

FIG. 13 is a diagram for explaining a state and a signal according to the first embodiment of the present technology.

FIG. 14 is a diagram illustrating a configuration example of a switch circuit according to a second embodiment of the present technology.

FIG. 15 is a diagram illustrating an example of a connection state of the switch circuit according to the second embodiment of the present technology.

FIG. 16 is a diagram illustrating another example of the connection state of the switch circuit according to the second embodiment of the present technology.

FIG. 17 is a block diagram illustrating a configuration example of an FPGA according to a third embodiment of the present technology.

FIG. 18 is a circuit diagram illustrating a configuration example of a logical configuration unit according to the third embodiment of the present technology.

FIG. 19 is a block diagram illustrating a configuration example of an electronic device according to a first modification of the third embodiment of the present technology.

FIG. 20 is a diagram for explaining a state according to the first modification of the third embodiment of the present technology.

FIG. 21 is a block diagram illustrating a configuration example of the FPGA according to a second modification of the third embodiment of the present technology.

FIG. 22 is a circuit diagram illustrating a configuration example of a check circuit, a resonance circuit, and an auxiliary power supply unit according to the second modification of the third embodiment of the present technology.

FIG. 23 is a circuit diagram illustrating another example of the auxiliary power supply unit according to the second modification of the third embodiment of the present technology.

FIG. 24 is a diagram for explaining a state according to the second modification of the third embodiment of the present technology.

FIG. 25 is a block diagram illustrating a configuration example of the FPGA according to a third modification of the third embodiment of the present technology.

FIG. 26 is a diagram for explaining a state according to the third modification of the third embodiment of the present technology.

FIG. 27 is a block diagram illustrating a configuration example of an electronic device according to a fourth embodiment of the present technology.

FIG. 28 is a diagram for explaining a state according to the fourth embodiment of the present technology.

FIG. 29 is a block diagram illustrating a configuration example of a large scale integration (LSI) according to a first modification of the fourth embodiment of the present technology.

FIG. 30 is a diagram for explaining a state according to the first modification of the fourth embodiment of the present technology.

FIG. 31 is a block diagram illustrating a configuration example of the LSI according to a second modification of the fourth embodiment of the present technology.

FIG. 32 is a block diagram illustrating a configuration example of the LSI according to a third modification of the fourth embodiment of the present technology.

FIG. 33 is a block diagram illustrating a schematic configuration example of a vehicle control system.

FIG. 34 is an explanatory diagram illustrating an example of an installation position of an imaging section.

### MODE FOR CARRYING OUT THE INVENTION

A mode for carrying out the present technology (hereinafter, referred to as an embodiment) will be described below. The description will be given in the following order.
1. First Embodiment (Example of Disposing Long-term Holding Memory and Short-term Holding Memory)
2. Second Embodiment (Example of Disposing Long-term Holding Memory and Short-term Holding Memory and Using 3D Cross-point Structure)
3. Third Embodiment (Example of Disposing Long-term Holding Memory and Plurality of Short-term Holding Memories having Different Data Holding Times)
4. Fourth Embodiment (Example of Disposing Long-term Holding Memory and Short-term Holding Memory in LSI)
5. Application Example to Mobile Body

### 1. First Embodiment

### [Configuration Example of Electronic Device]

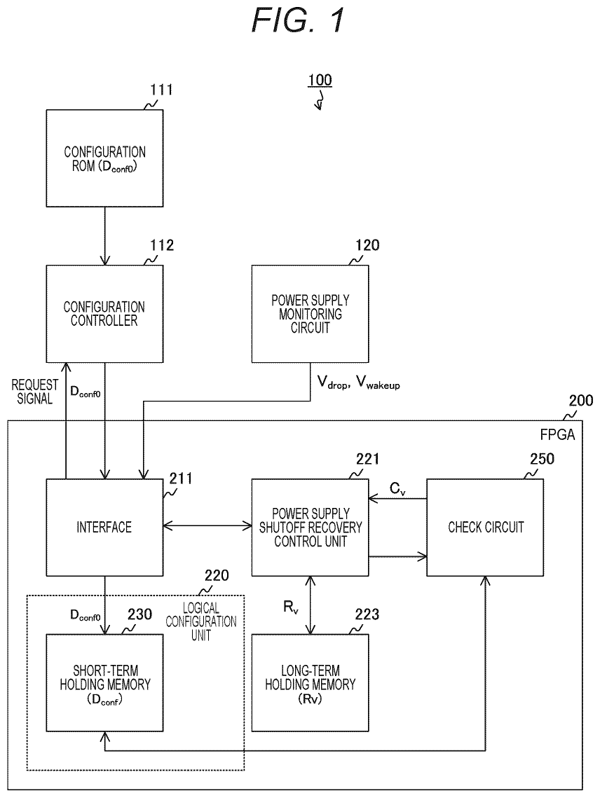

FIG. 1 is a block diagram illustrating a configuration example of an electronic device 100 according to a first embodiment of the present technology. This electronic device 100 includes a configuration read only memory (ROM) 111, a configuration controller 112, a power supply monitoring circuit 120, and an FPGA 200. The FPGA 200 includes an interface 211, a logical configuration unit 220, a power supply shutoff recovery control unit 221, a long-term holding memory 223, and a check circuit 250. Note that the FPGA 200 is an example of a semiconductor integrated circuit described in the claims.

The interface 211 exchanges various types of data between the configuration controller 112 and the power supply monitoring circuit 120, and the logical configuration unit 220.

The logical configuration unit 220 is a circuit whose circuit configuration can be changed by rewriting configuration data D_{conf}, and includes a short-term holding memory 230.

The long-term holding memory 223 is a memory whose data holding time is longer than that of the short-term holding memory 230, and the data holding time thereof is denoted as T_{NV}. The total number of memory cells of the long-term holding memory 223 is preferably smaller than the number of memory cells of the short-term holding memory 230.

The short-term holding memory 230 is disposed in the logical configuration unit 220. The short-term holding memory 230 is a memory whose data holding time is T_{LP} that is shorter than T_{NV}, and holds the configuration data D_{conf}. The configuration data D_{conf} is referred to as program data in some cases.

The long-term holding memory 223 holds specific data Rv indicating whether or not the power supply voltage is recovered after dropping to a value lower than a constant voltage V_{low} due to an instantaneous power failure, a power shutoff, or the like.

The power supply shutoff recovery control unit 221 controls the configuration controller 112 as necessary to reconfigure the short-term holding memory 230 in a case where an instantaneous power failure or the like occurs. The power supply shutoff recovery control unit 221 is mounted as dedicated hardware including a flip-flop or a latch constituted of a memory cell having a data holding time of T_{NV}, and a logical circuit. Here, the reconfiguration of the short-term holding memory 230 means that the configuration data D_{conf} in the short-term holding memory 230 is updated by the initial configuration data D_{conf0} read from the configuration ROM 111. By this update, the initial configuration data D_{conf0} is held in the short-term holding memory 230 as new configuration data D_{conf}.

The power supply shutoff recovery control unit 221 receives a voltage drop signal V_{drop} or a power supply recovery signal V_{wakeup} from the power supply monitoring circuit 120 via the interface 211. The voltage drop signal V_{drop} is a signal generated when the power supply voltage drops to a value lower than the constant voltage V_{low}. The power supply recovery signal V_{wakeup} is a signal generated when the power supply voltage recovers to a value exceeding a constant voltage V_{actlow}. In order to prevent the voltage drop and the detection of the power supply recovery from being repeatedly detected due to a voltage fluctuation in the vicinity of V_{low}, V_{actlow} is set to a value equal to or more than V_{low}.

In a case where the voltage drop signal V_{drop} is input (that is, the power supply voltage drops), the power supply shutoff recovery control unit 221 writes and holds Rv having a value (for example, “1”) different from the initial value (for example, “0”) in the long-term holding memory 223. Then, in a case where the power supply recovery signal V_{wakeup} is input (that is, the power supply voltage is recovered), the power supply shutoff recovery control unit 221 reads Rv from the long-term holding memory 223 and refers thereto, and determines whether or not Rv has the initial value. Because the data holding time of the long-term holding memory 223 is T_{NV}, in a case where Rv is updated to a value other than the initial value, it indicates that an instantaneous power failure or the like has occurred.

Therefore, in a case where an instantaneous power failure or the like has occurred, the power supply shutoff recovery control unit 221 refers to a determination result Cv from the check circuit 250 and determines whether or not at least a part of the configuration data D_{conf} is lost. In a case where at least a part of the configuration data D_{conf} is lost, the power supply shutoff recovery control unit 221 transmits a request signal for requesting reconfiguration to the configuration controller 112 via the interface 211.

The check circuit 250 determines whether or not at least a part of the configuration data D_{conf} held in the short-term holding memory 230 is lost. The check circuit 250 supplies the determination result Cv to the power supply shutoff recovery control unit 221.

The configuration read only memory (ROM) 111 is a read only memory that stores predetermined initial configuration data D_{conf0}. Note that the configuration read only memory (ROM) 111 is an example of a read only memory described in the claims.

The configuration controller 112 reads the initial configuration data D_{conf0} from the configuration ROM 111 according to a request signal from the FPGA 200, and updates (in other words, reconfigures) the configuration data D_{conf} in the short-term holding memory 230 according to the information.

The power supply monitoring circuit 120 monitors a power supply voltage of the FPGA 200. The power supply monitoring circuit 120 generates the voltage drop signal V_{drop} upon detecting that the power supply voltage is dropped to a value lower than the constant voltage V_{low}, and supplies the voltage drop signal V_{drop} to the power supply shutoff recovery control unit 221 via the interface 211.

Furthermore, the power supply monitoring circuit 120 generates the power supply recovery signal V_{wakeup} upon detecting that the power supply voltage is recovered to a value exceeding the constant voltage V_{actlow}, and supplies the power supply recovery signal V_{wakeup} to the power supply shutoff recovery control unit 221 via the interface 211.

In general, the short-term holding memory 230 having a short data holding time is smaller in power consumption and area at the time of writing than the long-term holding memory 223. Therefore, by using the short-term holding memory 230 as the memory that holds the configuration data D_{conf}, the power consumption and the area at the time of writing can be reduced as compared with a case where all the memories are long-term holding memories.

Furthermore, because the specific data Rv indicating whether or not the instantaneous power failure or the like has occurred is held in the long-term holding memory 223, the power supply shutoff recovery control unit 221 can determine whether or not the instantaneous power failure or the like has occurred by referring to the value. Therefore, at the time of activation, the check circuit 250 can determine the presence or absence of data loss in the short-term holding memory 230 only in the case of recovery from the instantaneous power failure or the like. Then, only in the case of data loss, the power supply shutoff recovery control unit 221 can cause the configuration controller 112 to perform reconfiguration. With this arrangement, upon recovering from the instantaneous power failure or the like and reactivating, unnecessary access or unnecessary reconfiguration is not performed, and the time required for reactivation can be shortened.

Note that, in a case where all the memories are the short-term holding memories 230, it is not possible to determine whether or not the instantaneous power failure or the like has occurred. Therefore, the FPGA 200 needs to access the short-term holding memory 230 and determine the presence or absence of data loss every time the FPGA 200 is activated. Furthermore, in a case where the check circuit 250 is not provided, it is necessary to perform reconfiguration at the time of reactivation regardless of the presence or absence of data loss. There is a possibility that the time required for reactivation becomes long due to such unnecessary access and unnecessary reconfiguration.

### [Configuration Example of Power Supply Monitoring Circuit]

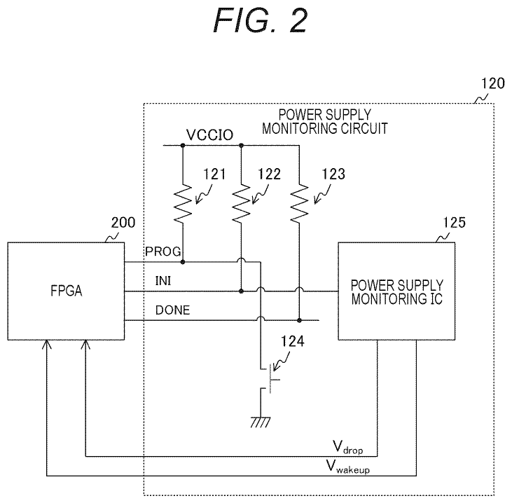

FIG. 2 is a circuit diagram illustrating a configuration example of the power supply monitoring circuit 120 according to the first embodiment of the present technology. The power supply monitoring circuit 120 includes resistors 121 to 123, a reset switch 124, and a power supply monitoring integrated circuit (IC) 125.

The resistor 121 is inserted between a power supply voltage VCCIO and a signal line connecting the FPGA 200 and the reset switch 124. The resistor 122 is inserted between the power supply voltage VCCIO and a signal line connecting the FPGA 200 and the power supply monitoring IC 125. The resistor 123 is inserted between the power supply voltage VCCIO and a signal line that transmits an output signal DONE.

The reset switch 124 initializes the power supply voltage of the FPGA 200. The power supply monitoring IC 125 monitors the power supply voltage of the FPGA 200, generates the voltage drop signal V_{drop} or the power supply recovery signal V_{wakeup}, and supplies the voltage drop signal V_{drop} or the power supply recovery signal V_{wakeup} to the FPGA 200.

### [Configuration Example of Logical Configuration Unit]

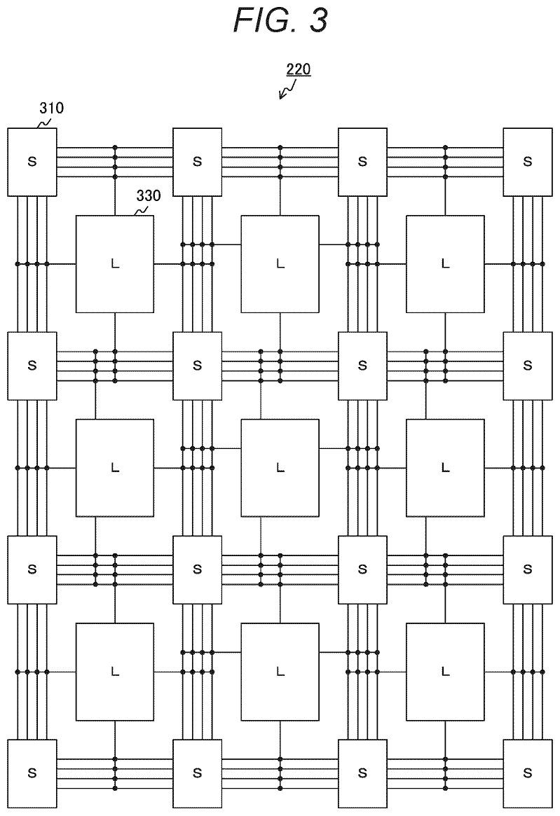

FIG. 3 is a circuit diagram illustrating a configuration example of the logical configuration unit 220 according to the first embodiment of the present technology. The logical configuration unit 220 includes a predetermined number of switch blocks 310 and a predetermined number of logical blocks 330. A block “S” in the drawing indicates the switch block 310, and a block “L” indicates the logical block 330.

In the switch block 310, memory cells having the data holding time of T_{LP} are disposed. In the logical block 330, memory cells having the data holding time of T_{LP} are disposed. A memory including memory cells having the data holding time of T_{LP} corresponds to the above-described short-term holding memory 230.

Note that the power supply shutoff recovery determination unit 221 is mounted as dedicated hardware outside the logical configuration unit 220, but is not limited to this configuration. A long-term holding memory can be further disposed in the logical configuration unit 220, and the function of the power supply shutoff recovery control unit 221 can be realized by the logical block 340 and the switch block 310.

### [Configuration Example of Switch Block]

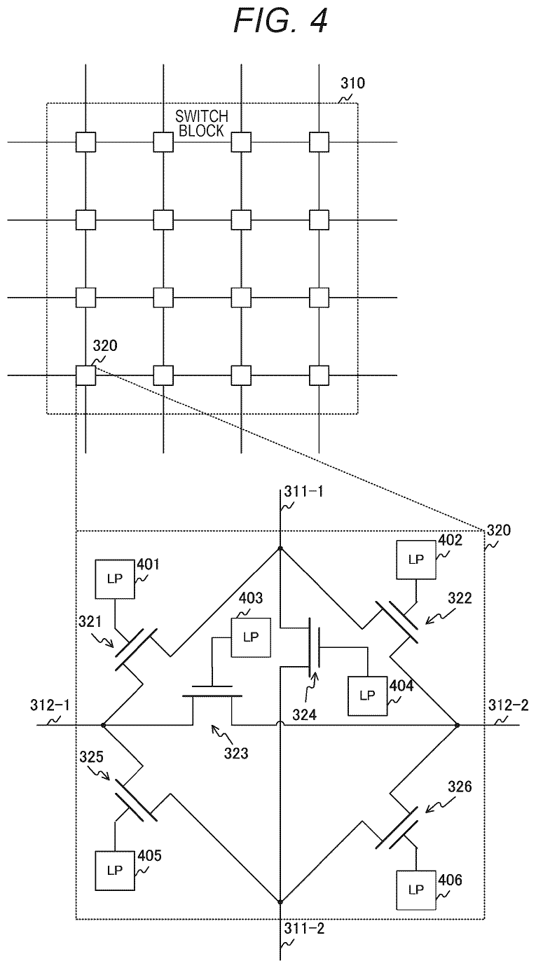

FIG. 4 is a circuit diagram illustrating a configuration example of the switch block 310 according to the first embodiment of the present technology. A predetermined number of horizontal signal lines and a predetermined number of vertical signal lines are wired in the switch block 310. A switch circuit such as the switch circuits 320 and 327 is disposed at each of intersections of the horizontal signal lines and the vertical signal lines.

The switch circuit 320 includes n-channel metal oxide semiconductor (nMOS) transistors 321 to 326 and memory cells 401 to 406. The nMOS transistor 321 is inserted between a horizontal signal line 312-1 and a vertical signal line 311-1. The nMOS transistor 322 is inserted between a horizontal signal line 312-2 and the vertical signal line 311-1. The nMOS transistor 323 is inserted between the horizontal signal line 312-1 and the horizontal signal line 312-2.

The nMOS transistor 324 is inserted between the vertical signal line 311-1 and a vertical signal line 311-2. The nMOS transistor 325 is inserted between the horizontal signal line 312-1 and the vertical signal line 311-2. The nMOS transistor 326 is inserted between the horizontal signal line 312-2 and the vertical signal line 311-2.

The data holding time of the memory cells 401 to 406 is T_{LP}, the memory cells being the ones provided in the short-term holding memory 230. The memory cell 401 is connected to the gate of the nMOS transistor 321 and holds connection information indicating whether or not the transistor connects the signal lines together. The memory cell 402 holds the connection information of the nMOS transistor 322. Similarly, the memory cells 403 to 406 each hold the connection information of corresponding one of the nMOS transistors 323 to 326.

### [Configuration Example of Memory Cell]

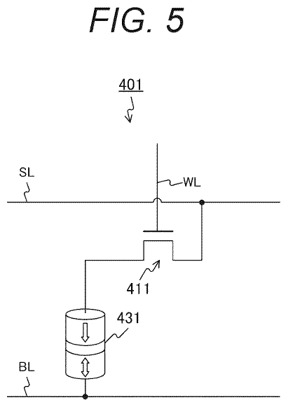

FIG. 5 is a circuit diagram illustrating a configuration example of the memory cell 401 according to the first embodiment of the present technology. The memory cell 401 includes an nMOS transistor 411 and a magnetic tunnel junction (MTJ) element 431. The nMOS transistor 411 and the MTJ element 431 are inserted in series between a source line SL and a bit line BL. Furthermore, the gate of the nMOS transistor 411 is connected to a word line WL. The memory cell 401 having the circuit configuration exemplified in the drawing is used in an MRAM.

The circuit configuration of the memory cells in the short-term holding memory 230 other than the memory cell 401 is similar to that of the memory cell 401. Furthermore, the circuit configuration of the memory cell in the long-term holding memory 223 is similar to that of the memory cell 401, but the ferromagnet constituting a storage layer in the MTJ element is different.

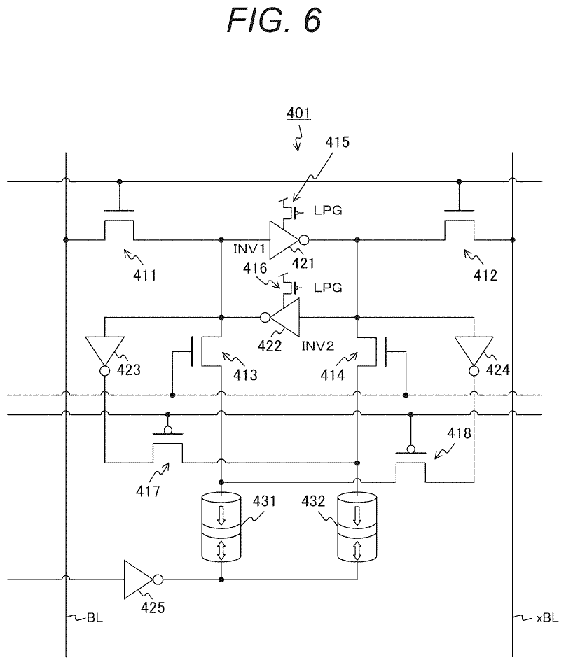

Note that the circuit configuration of the memory cell such as the memory cell 401 is not limited to that exemplified in the drawing, and may be a circuit configuration of a non-volatile SRAM as exemplified in FIG. 6. In the memory cell 401 of the non-volatile SRAM, nMOS transistors 411 to 414, p-channel MOS (pMOS) transistors 415 to 418, inverters 421 to 425, and MTJ elements 431 and 432 are disposed. Furthermore, data read from the memory cell 401 is output from a bit line BL, and inverted data of the data is output from a bit line xBL.

Furthermore, as illustrated in FIG. 5, the present invention has been disclosed by using a magnetic storage element, but the present invention is not limited to this configuration, and a phase-change memory (PCM) or a resistive random access memory (ReRAM) can also be used. In the PCM, a non-volatile memory having characteristics of short-term holding and long-term holding can be mixedly mounted by adjusting a material according to “Nitrogen doping-induced local structure change in a Cr2Ge2Te6 inverse resistance phase-change material, Mater. Adv., 1, pp. 2426-2432, 2020.”. In the ReRAM, a non-volatile memory having characteristics of short-term holding and long-term holding can be mixedly mounted by adjusting an oxide film or limiting the maximum current by a circuit according to “Mass production of resistance change memory based on oxide material design and reliability modeling, PhD thesis, Nagoya University, 2016.”. As described above, it is obvious that the present invention is also applicable to a case where these devices are used, and the present invention is not limited to a magnetic storage element (MRAM).

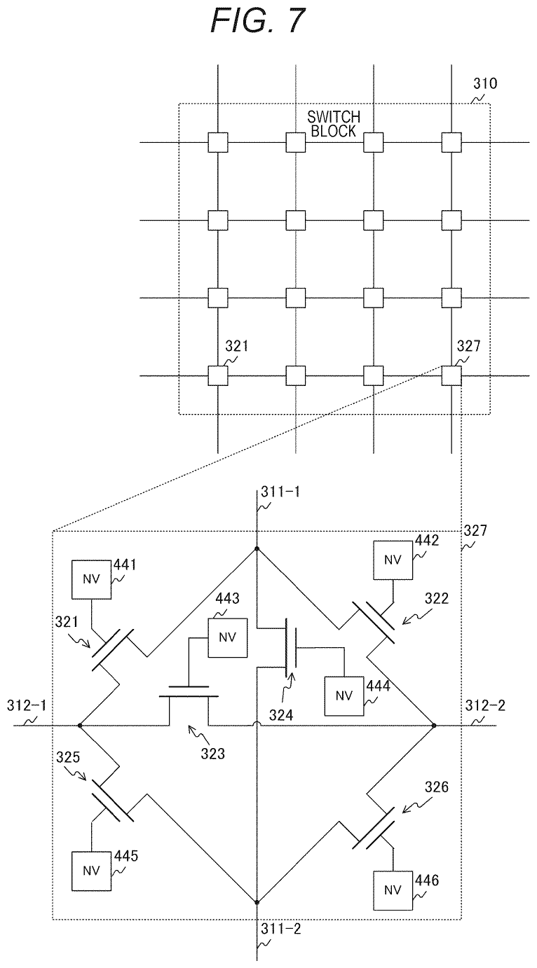

Note that, in a case where the power supply shutoff recovery determination unit 221 is mounted in the logical configuration unit 220 instead of being mounted as dedicated hardware, as exemplified in FIG. 7, a switch circuit 327 provided with memory cells 441 to 446 having the data holding time of T_{NV} is further disposed as necessary.

### [Configuration Example of Logical Block]

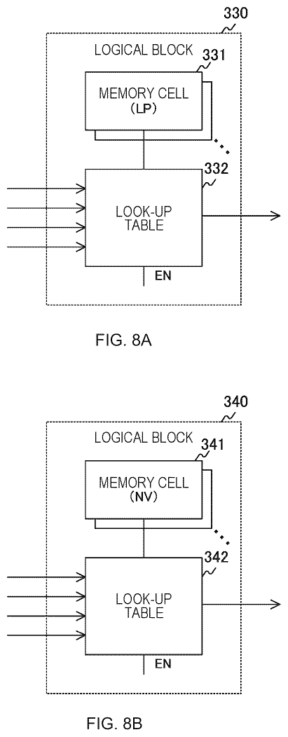

FIG. 8 is a block diagram illustrating a configuration example of the logical blocks 330 and 340 according to the first embodiment of the present technology. In the drawing, a is a block diagram of the logical block 330, and b in the drawing is a block diagram of the logical block 340.

As exemplified in a of the drawing, the logical block 330 includes a predetermined number of memory cells 331 and a look-up table 332. The data holding time of the memory cell 331 is T_{LP}, and each of the memory cells 331 is the one provided in the short-term holding memory 230. These memory cells hold wire connection information in the look-up table 332. Note that a plurality of look-up tables can be disposed in the logical block 330.

Note that, in a case where the power supply shutoff recovery determination unit 221 is mounted in the logical configuration unit 220 instead of being mounted as dedicated hardware, as exemplified in b of the drawing, the logical block 340 provided with memory cells 341 having the data holding time of T_{NV} is further disposed.

### [Configuration Example of Check Circuit]

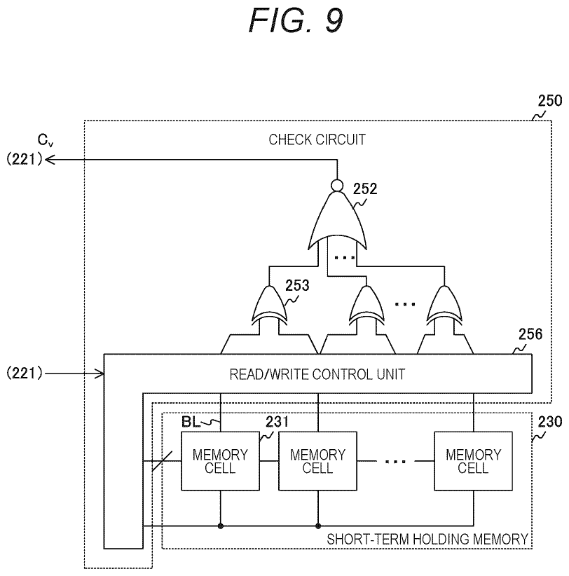

FIG. 9 is a circuit diagram illustrating a configuration example of the check circuit 250 according to the first embodiment of the present technology. The check circuit 250 includes a negative logical sum (NOR) gate 252 with a plurality of inputs, a plurality of exclusive logical sum (XOR) gates 253, and a read/write control unit 256.

The read/write control unit 256 reads data from the plurality of memory cells 231 in the short-term holding memory 230 under the control of the power supply shutoff recovery control unit 221. The number of these memory cells is denoted as N (N is an integer of 2 or more). In this case, the number of the XOR gates 253 is N−1.

Here, N pieces of the memory cells 231 may all be the memory cells of the non-volatile SRAM exemplified in FIG. 6, or may all be the MRAM memory cells exemplified in FIG. 5. Furthermore, all of these memory cells hold the same logical value. For example, the logical value “1” is held in all the memory cells. Alternatively, the logical value “0” is held in all the memory cells. Furthermore, the held value is read from the memory cell 231 via the bit line BL.

The nth (n is an integer of 1 to N−1) XOR gate 253 supplies the exclusive OR of the held values of the nth and (n+1)th memory cells 231, which are adjacent to each other, to the NOR gate 232. The NOR gate 252 supplies the negative OR of each output of the XOR gate 253 to the power supply shutoff recovery control unit 221 as the determination result Cv. The determination result Cv has a logical value “1” in a case where all the held values of N pieces of the memory cells 231 coincide with each other, and has a logical value “0” in a case where at least one of the held values does not coincide with the others.

Furthermore, at the time of data loss, the read/write control unit 256 writes and reconfigures the value before the loss in each of the plurality of memory cells 231 after the power supply recovers according to the control of the power supply shutoff recovery control unit 221.

With the configuration exemplified in FIG. 9, the check circuit 250 can determine whether or not all the held values of N pieces of the memory cells 231 coincide with each other. In a case where at least one value does not coincide with the others (that is, Cv is “0”), it is determined that at least a part of the configuration data is lost.

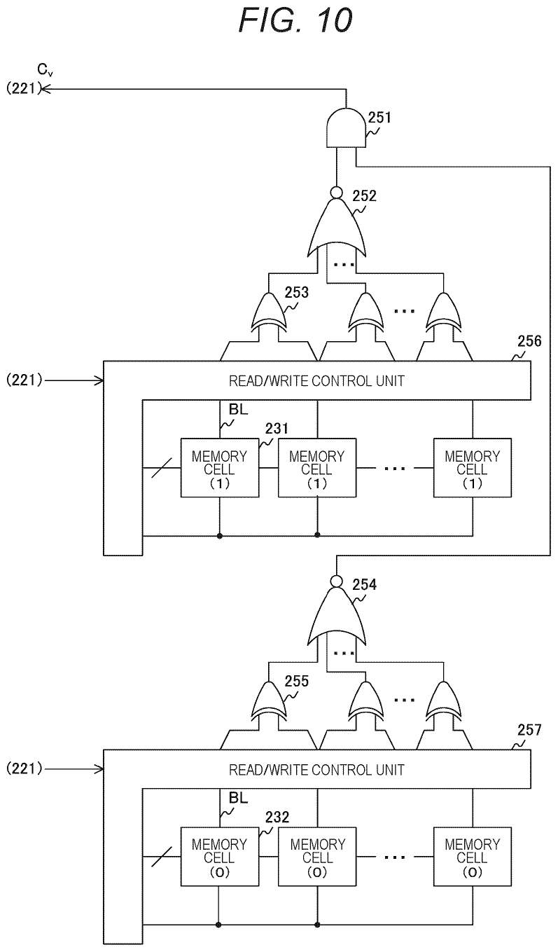

Note that the check circuit 250 is not limited to the configuration exemplified in the drawing. As exemplified in FIG. 10, both the plurality of memory cells 231 holding the logical value “1” and the plurality of memory cells 232 holding the logical value “0” can be read. The number of memory cells 231 is N1 (N1 is an integer of 2 or more), and the number of memory cells 232 is N2 (N2 is an integer of 2 or more). In this case, the check circuit 250 further includes a logical product (AND) gate 251, a plurality of XOR gates 255, a NOR gate 254, and a read/write control unit 257. In this case, the number of the XOR gates 253 is N1−1, and the number of the XOR gates 255 is N2−1.

The held value is read from the memory cell 232 via the bit line BL. The read/write control unit 257 reads data from N2 pieces of the memory cells 231 according to the control of the power supply shutoff recovery control unit 221, and each of the XOR gates 255 configures N2−1 pieces of XOR gate outputs of the read values of the adjacent memory cells 232, inputs all the output values to the NOR gate 254, and obtains an output of the NOR gate 254. Similarly, for Ni pieces of the memory cells 231, N1−1 pieces of XOR gate outputs of the read values of the adjacent memory cells are configured, and all the output values are input to the NOR gate 252 to obtain an output of the NOR gate 252. The two NOR gate outputs are output to the AND gate 251.

The AND gate 251 supplies the AND of the output signals of the NOR gates 252 and 254 to the power supply shutoff recovery control unit 221 as the determination result Cv. The determination result Cv becomes a logical value “1” in a case where all the held values of Ni pieces of the memory cells 231 coincide with each other and all the held values of N2 pieces of the memory cells 232 coincide with each other. With this arrangement, the check circuit 250 can determine whether or not at least one of the data loss of the logical value “1” and the data loss of the logical value “0” has occurred.

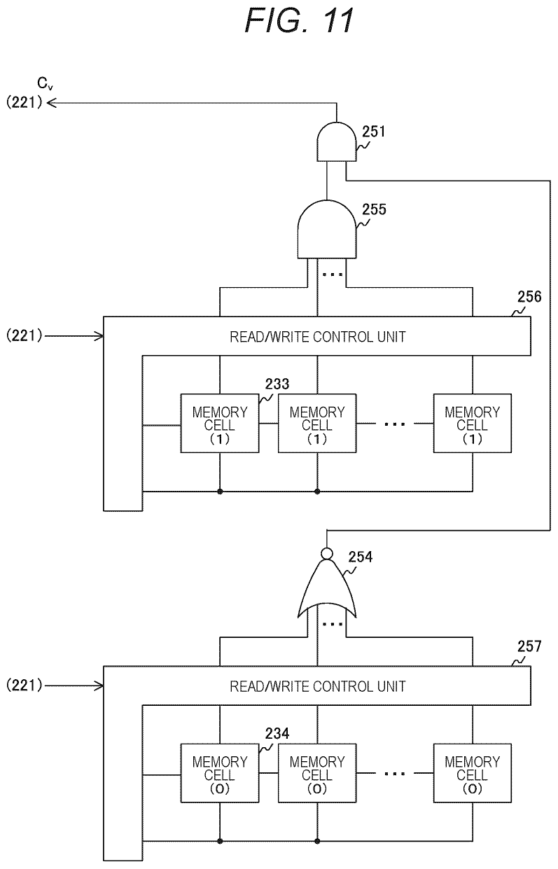

Furthermore, as exemplified in FIG. 5, the check circuit 250 can configure all the cells as memory cells of the MRAM and read data therefrom, or can configure all the cells as memory cells in FIG. 6 and read data therefrom. Furthermore, as exemplified in FIG. 11, instead of the two-stage logical circuit of the plurality of XOR gates and NOR gates, an AND gate 255 and the NOR (negative OR) gate 254 can be disposed in the check circuit 250. Furthermore, a plurality of memory cells 233 and a plurality of memory cells 234 are disposed in the short-term holding memory 230. The number of memory cells 233 is N1, and the number of memory cells 234 is N2.

A logical value “1” is held in N1 pieces of the memory cells 233, and a logical value “0” is held in N2 pieces of the memory cells 234. The AND gate 255 supplies the AND of the respective held values of the memory cells 233 to the AND gate 251. The NOR gate 254 supplies the negative AND of the respective held values of the memory cells 234 to the AND gate 251.

The AND gate 251 supplies the AND of the output signals of the AND gate 255 and the NOR gate 254 to the power supply shutoff recovery control unit 221 as the determination result Cv. The determination result Cv becomes a logical value “1” in a case where all the held values of Ni pieces of the memory cells 233 coincide with each other and all the held values of N2 pieces of the memory cells 234 coincide with each other.

### [Operation Example of FPGA]

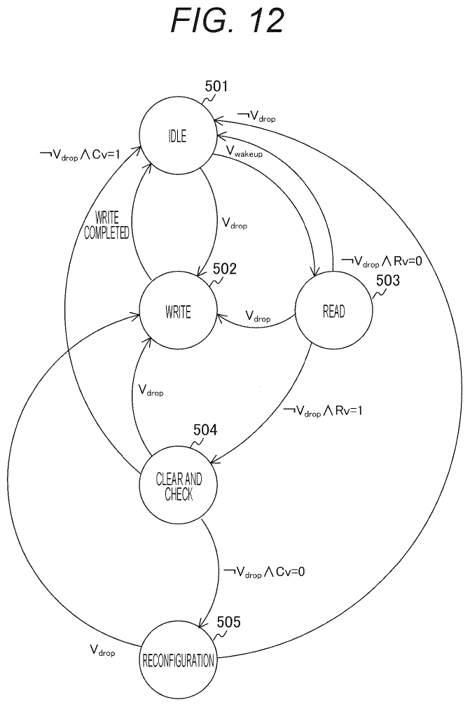

FIG. 12 is an example of a state transition diagram of the power supply shutoff recovery control unit 221 according to the first embodiment of the present technology. The power supply shutoff recovery control unit 221 is implemented as a state machine.

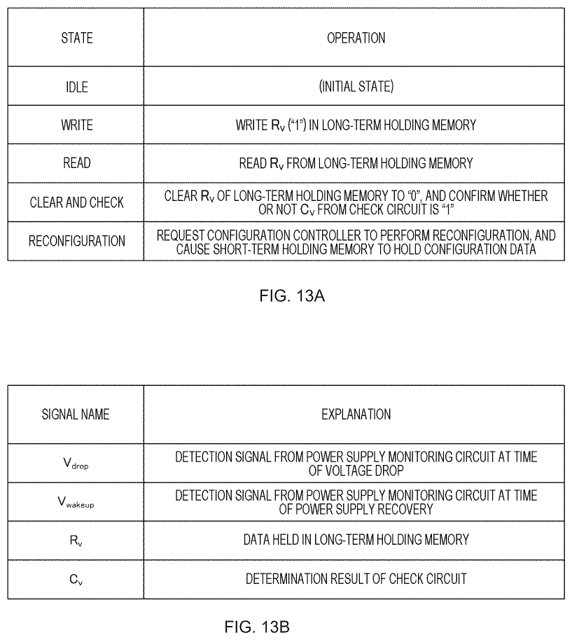

The operation in each state in FIG. 12 is illustrated in a of FIG. 13. Furthermore, an explanation of signals exchanged in FIG. 12 is illustrated in b of FIG. 13.

As exemplified in FIG. 12, in a case where the power supply is turned on or in a case where the power supply is recovered from the power supply drop, the power supply shutoff recovery control unit 221 shifts to an idle state 501 which is the initial state. In the idle state 501, in a case where the voltage drop signal V_{drop} is input, the power supply shutoff recovery control unit 221 shifts to a write state 502, and in a case where the power supply recovery signal V_{wakeup} is input, the power supply shutoff recovery signal 221 shifts to a read state 503.

In the write state 502, the power supply shutoff recovery control unit 221 writes Rv having a value (such as “1”) different from the initial value to the long-term holding memory 223, and transitions to the idle state 501.

In the read state 503, the power supply shutoff recovery control unit 221 reads Rv from the long-term holding memory 223. Then, when the voltage drop signal V_{drop} is input, the power supply shutoff recovery control unit 221 shifts to the write state 502. Furthermore, in a case where the voltage drop signal V_{drop} is not input and Rv is “0”, the power supply shutoff recovery control unit 221 shifts to the idle state 501. On the other hand, in a case where the voltage drop signal V_{drop} is not input and Rv is “1”, the power supply shutoff recovery control unit 221 shifts to a clear and check state 504.

In the clear and check state 504, the power supply shutoff recovery control unit 221 sets Rv to the initial value (such as “0”), acquires the determination result Cv from the check circuit 250, and confirms whether or not the acquired value is “1”. Then, when the voltage drop signal V_{drop} is input, the power supply shutoff recovery control unit 221 shifts to the write state 502. Furthermore, in a case where the voltage drop signal V_{drop} is not input and Cv is “0” (that is, at least a part of the configuration data is lost), the power supply shutoff recovery control unit 221 shifts to a reconfiguration state 505. On the other hand, in a case where the voltage drop signal V_{drop} is not input and Cv is “1”, the power supply shutoff recovery control unit 221 shifts to the idle state 501.

In the reconfiguration state 505, the power supply shutoff recovery control unit 221 requests the configuration controller 112 to perform reconfiguration, and causes the short-term holding memory 230 to hold the configuration data. The memory cell 231 to be checked is reconfigured to an appropriate value. Then, the power supply shutoff recovery control unit 221 shifts to the write state 502 in a case where the voltage drop signal V_{drop} is input, and shifts to the idle state 501 in a case where the voltage drop signal V_{drop} is not input.

As described above, according to the first embodiment of the present technology, the FPGA 200 holds the configuration data in the short-term holding memory 230, and holds Rv indicating whether or not the instantaneous power failure has occurred in the long-term holding memory 223. With this arrangement, the power consumption and the area at the time of writing can be reduced as compared with a case where all the memories are long-term holding memories. Furthermore, the FPGA 200 can shorten the time required for reactivation by performing the reconfiguration only in the case of data loss at the time of the instantaneous power failure.

### 2. Second Embodiment

In the first embodiment described above, the memory cell of the nonvolatile SRAM or the MRAM is disposed in the switch circuit 320, but in this configuration, it is difficult to further reduce the mounting area. An FPGA 200 according to a second embodiment is different from that in the first embodiment in that the mounting area is reduced by using a 3D cross-point type memory.

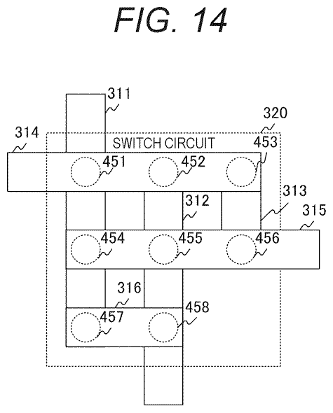

FIG. 14 is a diagram illustrating a configuration example of a switch circuit 320 according to the second embodiment of the present technology. Word lines 314, 315, and 316 are wired in the horizontal direction in a predetermined layer in the switch circuit 320 of the second embodiment. Bit lines 311, 312, and 313 are wired in the vertical direction in the lower layer of the word lines.

Then, memory cells 451, 452, and 453 are disposed at intersections of the bit lines 311, 312, and 313 and the word line 314. Memory cells 454, 455, and 456 are disposed at intersections of the bit lines 311, 312, and 313 and the word line 315. Memory cells 457 and 458 are disposed at intersections of the bit lines 311 and 312 and the word line 316. As exemplified in the drawing, the mounting area can be reduced by using the 3D cross-point structure. The configuration of a switch circuit 327 is similar to that exemplified in the drawing except that the data holding time of the memory cell is different.

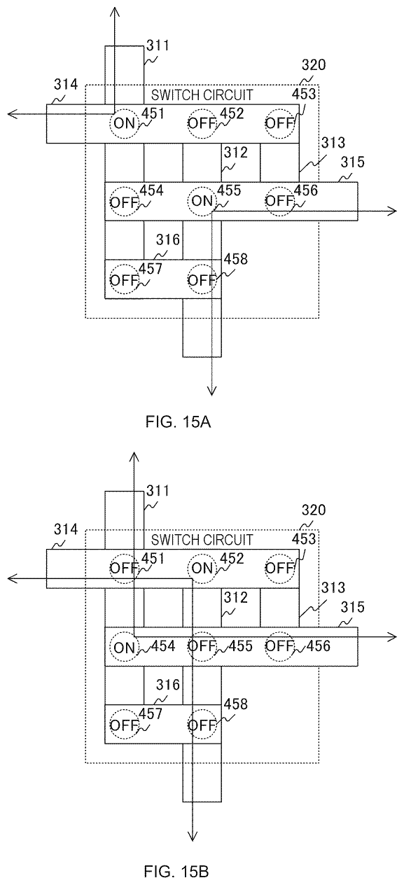

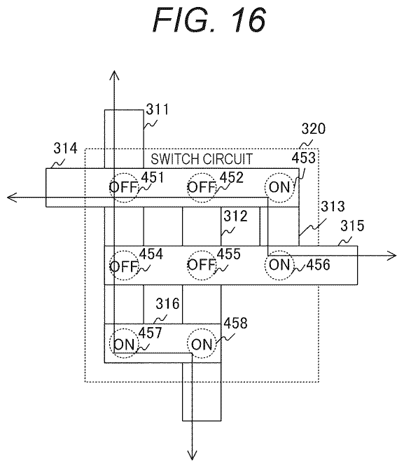

FIGS. 15 and 16 are diagrams each illustrating an example of a connection state of the switch circuit 320 according to the second embodiment of the present technology. In these drawings, arrows indicate directions in which data is transmitted.

As exemplified in a of FIG. 15, by turning on the memory cells 451 and 455 and turning off the rest of the memory cells, the word line 314 and the bit line 311 can be connected, and the word line 315 and the bit line 312 can be connected.

Furthermore, as exemplified in b of FIG. 15, by turning on the memory cells 452 and 454 and turning off the rest of the memory cells, the word line 314 and the bit line 312 can be connected, and the word line 315 and the bit line 311 can be connected.

Furthermore, as exemplified in FIG. 16, the memory cells 453, 456, 457, and 458 can be turned on, and the rest of the memory cells can be turned off. In this case, the word lines 314 and 315 are connected to the bit line 313, and the word line 316 is connected to the bit lines 311 and 312.

As described above, according to the second embodiment of the present technology, because the 3D cross-point structure is used, the mounting area of a short-term holding memory 230 can be reduced.

### 3. Third Embodiment

In the first embodiment described above, the data holding times of the memory are separately set in two stages, which are T_{LP} and T_{NV}, but the data holding times may be separately set in three or more stages. An FPGA 200 of a third embodiment is different from that of the first embodiment in that a short-term holding memory 230 and a short-term holding memory 240 having different data holding times are disposed in addition to a long-term holding memory 223.

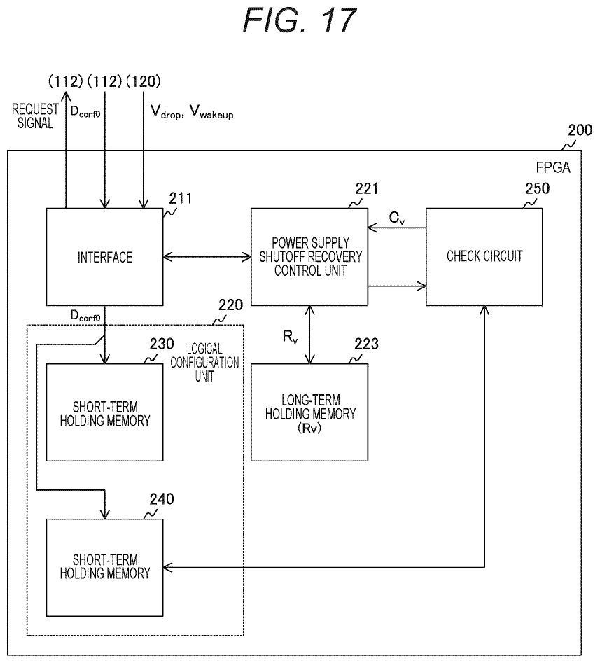

FIG. 17 is a block diagram illustrating a configuration example of the FPGA 200 according to the third embodiment of the present technology. The FPGA 200 of the third embodiment is different from that of the first embodiment in further including the short-term holding memory 240.

The short-term holding memories 230 and 240 have different data holding times from each other. Assuming that the data holding time of the short-term holding memory 230 is T_{LP2} and the data holding time of the short-term holding memory 240 is T_{LP1}, the following relational expression is satisfied.

T_{NV}>T_{LP2}>T_{LP1}

A part of the configuration data is written to the short-term holding memory 230, and the rest of data is written to the short-term holding memory 240. Furthermore, a check circuit 250 determines the presence or absence of loss of data held in the short-term holding memory 240 having the shortest data holding time.

Furthermore, in a case where the check circuit 250 determines that the data in the short-term holding memory 240 is lost, a power supply shutoff recovery control unit 221 controls a configuration controller 112 to reconfigure both of the short-term holding memories 230 and 240.

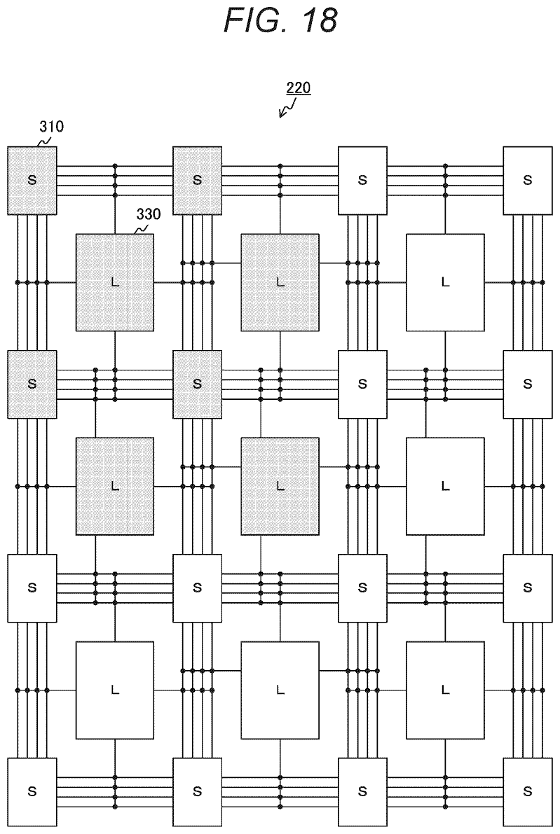

FIG. 18 is a circuit diagram illustrating a configuration example of a logical configuration unit according to the third embodiment of the present technology.

Among a predetermined number of logical blocks 340, memory cells in the short-term holding memory 230 having the longer data holding time are disposed in a gray logical block and a gray switch block 310. Memory cells in the short-term holding memory 240 having the shortest data holding time are disposed in the white logical block and the white switch block 310.

Because the data holding time of the short-term holding memory can be widely set from several seconds to several days, memory cells having different data holding times can be mixed as exemplified in the drawing. A method of setting the data holding time of the memory cell is described, for example, in FIG. 10(a) of “M. Oka, et al., 3D stacked CIS compatible 40 nm embedded STT-MRAM for buffer memory, In Proc. of VLSI Sympo. 2021.”.

As exemplified in the drawing, by setting the data holding times in three stages, the number of memory cells to be checked can be reduced as compared with the case of two stages.

Note that, although the data holding times are set in three stages, the data holding time may be set in four or more stages. In this case, K (K is an integer of 3 or more) pieces of the short-term holding memories having different data holding times are disposed. In a case where the data holding times of the short-term holding memory are set in three stages, the FPGA 200 can be divided into a large-scale region having the largest area, a medium-scale region, and a small-scale region having the smallest area. In this case, a memory cell having the shortest data holding time (such as several seconds) is disposed in the large-scale region. A memory cell having the next shortest data holding time (for example, several hours) is disposed in the medium-scale region. A memory cell having the longest data holding time (for example, several days) is disposed in the small-scale region.

In a case where the data holding times are set in three or more stages, the following two methods are conceivable as a checking method of the check circuit 250.

(i) The check circuit 250 determines the presence or absence of loss of the data held in the short-term holding memory having the shortest data holding time.

(ii) The check circuit 250 determines the presence or absence of loss of the held data for each of the short-term holding memory having the shortest data holding time to the short-term holding memory having the kth (k is an integer of 2 or more) shortest data holding time.

Furthermore, the following two methods are conceivable as a control method of the power supply shutoff recovery control unit 221.

(iii) When the data in the short-term holding memory having the shortest data holding time is lost, the power supply shutoff recovery control unit 221 reconfigures all of K pieces of the short-term holding memories. This control is performed in a case the checking method of (i) is used.

(iv) If the number of short-term holding memory cells whose data has been lost is more than k−1 (k is an integer of 2 or more), the power supply shutoff recovery control unit 221 reconfigures all of K pieces of the short-term holding memories. On the other hand, if the number of the short-term holding memory cells whose data has been lost is k−1 or less, the power supply shutoff recovery control unit 221 selects a memory cell having the longest data holding time among the lost short-term holding memory cells, and assuming that, when the length of the data holding time of the memory cell is counted in order from the longest one among k pieces of the memory cells and the order of the memory cell from the top is m-th, reconfigures all the memory cells whose order is m-th or less. This control is performed in a case where the checking method of (ii) is used.

Note that the second embodiment can be applied to the third embodiment.

As described above, according to the third embodiment of the present technology, because the short-term holding memories 230 and 240 having different data holding times are disposed, the number of memory cells to be checked can be reduced.

### [First Modification]

In the third embodiment described above, a configuration ROM 111 and the configuration controller 112 are provided outside the FPGA 200, but these functions may be incorporated in the FPGA 200. The FPGA 200 according to a first modification of the third embodiment is different from that of the first embodiment in that the FPGA 200 has a function of a configuration controller and holds the initial configuration data in the long-term holding memory 223.

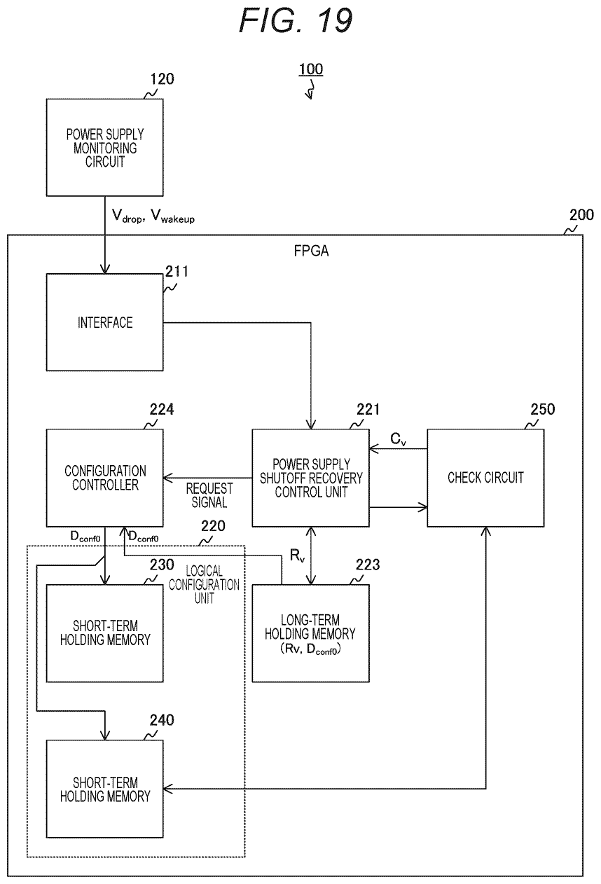

FIG. 19 is a block diagram illustrating a configuration example of an electronic device 100 according to the first modification of the third embodiment of the present technology. The electronic device 100 according to the first modification of the third embodiment is different from that of the third embodiment in that the configuration ROM 111 and the configuration controller 112 are not disposed outside the FPGA 200.

Furthermore, a configuration controller 224 is further disposed in the FPGA 200. Furthermore, in addition to Rv, initial configuration data D_{conf0} is further held in the long-term holding memory 223.

Furthermore, the power supply shutoff recovery control unit 221 and the configuration controller 224 are mounted as a state machine.

As exemplified in the drawing, by having the initial configuration data D_{conf0} held in the long-term holding memory 223, the external configuration ROM 111 can be reduced.

Furthermore, by having the function of the configuration controller 224 added, the external configuration controller 112 can be reduced.

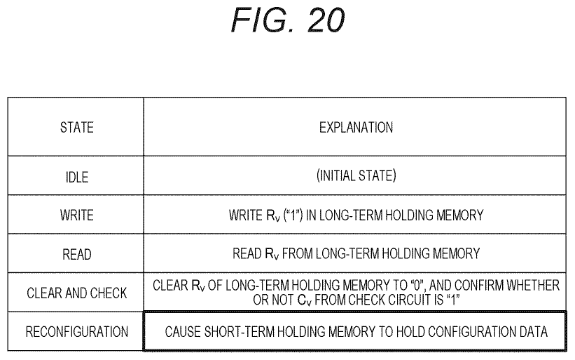

FIG. 20 is a diagram for explaining a state according to the first modification of the third embodiment of the present technology. A thick frame portion in the drawing indicates a portion different from that of the first embodiment. Only this different portion will be described. Upon transitioning to the reconfiguration state, the configuration controller 224 causes the short-term holding memories 230 and 240 to hold the configuration data.

Note that, in the first modification of the third embodiment, the data holding times can be set in two stages instead of three or more stages. Furthermore, the second embodiment can also be applied to the first modification of the third embodiment.

As described above, according to the first modification of the third embodiment of the present technology, because the initial configuration data D_{conf0} is held in the long-term holding memory 223, the external configuration ROM 111 can be reduced.

### [Second Modification]

In the third embodiment described above, the presence or absence of data loss is determined by reading the data from the short-term holding memory 240 and performing the logical operation, but the presence or absence of data loss can also be determined by a method other than the logical operation. The FPGA 200 according to a second modification of the third embodiment is different from that of the third embodiment in that presence or absence of data loss is determined by comparing an absolute value of a transient voltage of an LC resonance circuit with a reference voltage.

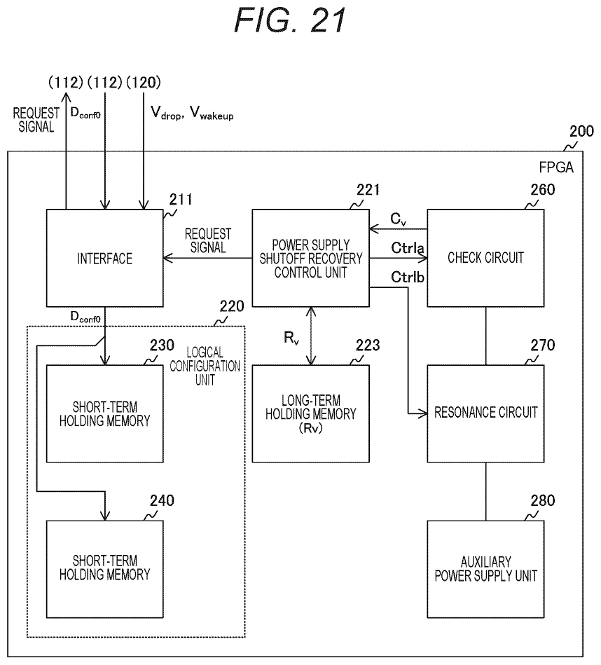

FIG. 21 is a block diagram illustrating a configuration example of the FPGA 200 according to the second modification of the third embodiment of the present technology. The FPGA 200 according to the second modification of the third embodiment includes a check circuit 260, a resonance circuit 270, and an auxiliary power supply unit 280 instead of the check circuit 250.

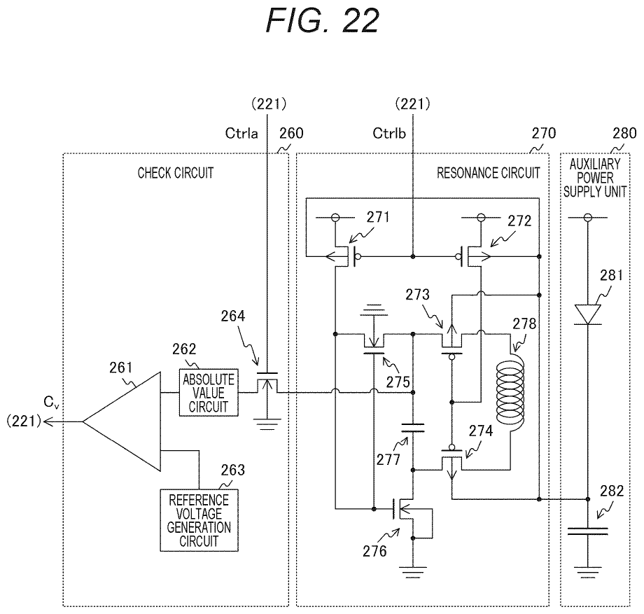

FIG. 22 is a circuit diagram illustrating a configuration example of the check circuit 260, the resonance circuit 270, and the auxiliary power supply unit 280 according to the second modification of the third embodiment of the present technology.

The auxiliary power supply unit 280 includes a diode 281 and a capacitive element 282. The diode 281 and the capacitive element 282 are connected in series between a power supply voltage and a ground voltage.

The resonance circuit 270 includes pMOS transistors 271 to 274, nMOS transistors 275 and 276, a capacitive element 277, and an inductive element 278.

The pMOS transistors 271 and 272 are connected in parallel to the power supply voltage. Back gates of the pMOS transistors 271 and 272 are commonly connected to a connection node of the diode 281 and the capacitive element 282. The control signal Ctrlb from the power supply shutoff recovery control unit 221 is input to the gates of the pMOS transistors 271 and 272.

The nMOS transistor 275 and the pMOS transistor 273 are connected in series between the drain of the pMOS transistor 271 and one end of the inductive element 278. Furthermore, the back gate of the nMOS transistor 275 is grounded, and the back gate of the pMOS transistor 273 is connected to the connection node of the diode 281 and the capacitive element 282.

The capacitive element 277 and the nMOS transistor 276 are connected in series between a connection node of the nMOS transistor 275 and the pMOS transistor 273 and a ground voltage. The back gate of the nMOS transistor 276 is grounded. The gates of the nMOS transistors 275 and 276 are commonly connected to the drain of the pMOS transistor 271.

The pMOS transistor 274 is inserted between the inductive element 278 and a connection node of the capacitive element 277 and the nMOS transistor 276. Furthermore, the back gate of the pMOS transistor 274 is connected to the connection node of the diode 281 and the capacitive element 282. The gates of the pMOS transistors 273 and 274 are connected to the drain of the pMOS transistor 272.

The check circuit 260 includes a comparison circuit 261, an absolute value circuit 262, a reference voltage generation circuit 263, and an nMOS transistor 264.

The reference voltage generation circuit 263 generates a predetermined reference voltage and supplies the reference voltage to the comparison circuit 261.

The nMOS transistor 264 is inserted between a connection node of the nMOS transistor 275 and the pMOS transistor 273 and the absolute value circuit 262. A voltage of this connection node becomes a transient voltage that fluctuates with the lapse of time when the power supply voltage is shut off. Furthermore, a control signal Ctrla from the power supply shutoff recovery control unit 221 is input to the gate of the nMOS transistor.

The absolute value circuit 262 acquires an absolute value of the transient voltage of the resonance circuit 270 input via the nMOS transistor 264, and supplies the absolute value to the comparison circuit 261.

The comparison circuit 261 compares the absolute value of the transient voltage with the reference voltage, and outputs a comparison result as a determination result Cv to the power supply shutoff recovery control unit 221.

In the auxiliary power supply unit 280, the capacitive element 282 is charged until the power supply voltage is shut off. Note that, although a power supply monitoring circuit 120 detects whether or not the power supply voltage drops below V_{low}, this voltage drop also includes shutoff of the power supply voltage. Hereinafter, a case where the power supply voltage is shut off is assumed.

In the resonance circuit 270, when the power supply voltage is shut off, the pMOS transistors 273 and 274 are turned on, and the nMOS transistors 275 and 276 are turned off. This causes an LC resonance circuit to be configured in the resonance circuit 270, and a resonance operation thereof is started. During the resonance operation, the transient voltage decays over time.

Note that the resonance operation is stopped by setting the control signal Ctrlb to “0” after the power supply is recovered.

In a case where the power supply is not shut off, the power supply shutoff recovery control unit 221 controls the control signal Ctrlb to “0”. This causes the check circuit 260 to be stopped. The value of Cv at this time is “1”.

After the power supply is recovered, the power supply shutoff recovery control unit 221 controls the control signal Ctrlb to “1”. With this arrangement, the check circuit 260 is activated and compares the absolute value of the transient voltage with the reference voltage. Because the transient voltage attenuates with the lapse of time, the absolute value of the transient voltage becomes lower than the reference voltage at a certain timing, and Cv is inverted from “1” to “0”. A time Td until Cv is inverted can be adjusted by the value of the reference voltage. Td is set to be longer than a data holding time T_{LP1} of the short-term holding memory 240.

The fact that the time from when the power supply is shut off to when the power supply is recovered is equal to or longer than Td (that is, Cv is “0”) indicates that at least a part of the configuration data is lost. The FPGA 200 can determine whether or not data is lost without reading the data from the memory cell and performing the logical operation by the circuit exemplified in the drawing.

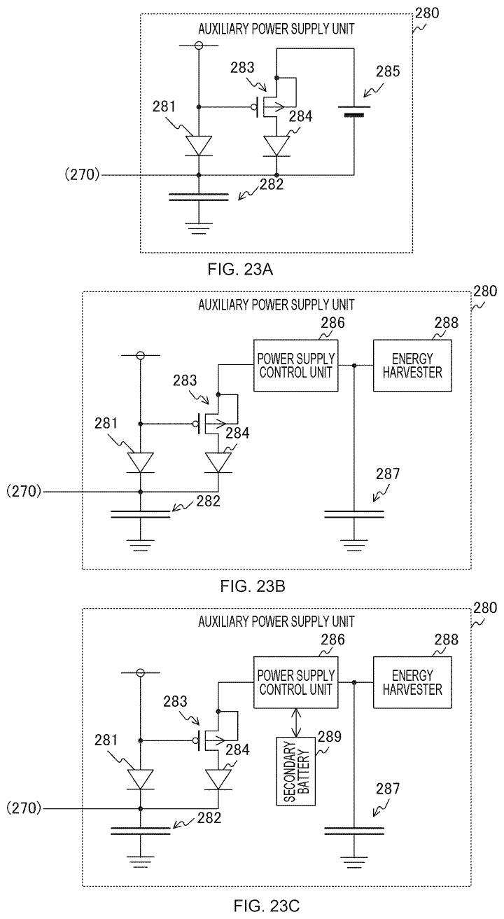

The resonance circuit 270 includes only four pMOS transistors, and power supply to the substrate provided with this circuit can be covered by a weak electromotive force. For example, any circuit among a, b, and c in FIG. 23 can be applied to the auxiliary power supply unit 280.

In the auxiliary power supply unit 280 exemplified in a of the drawing, a pMOS transistor 283, a diode 284, and a primary battery 285 are further provided. The pMOS transistor 283 and the diode 284 are connected in series between both ends of the primary battery 285. The gate of the pMOS transistor 283 is connected to the power supply voltage. Furthermore, a button battery or the like is used as the primary battery 285, and a negative terminal thereof is connected to a connection node of the diode 281 and the capacitive element 282.

In the auxiliary power supply unit 280 exemplified in b of the drawing, the pMOS transistor 283, the diode 284, a power supply control unit 286, a capacitive element 287, and an energy harvester 288 are further provided.

The pMOS transistor 283 and the diode 284 are connected in series between the connection node of the diode 281 and the capacitive element 282 and the power supply control unit 286. The gate of the pMOS transistor 283 is connected to the power supply voltage.

The energy harvester 288 performs energy harvesting. For example, ambient light is converted into electric power by photoelectric conversion. Alternatively, heat due to an ambient temperature difference is converted into electric power by thermoelectric conversion. Alternatively, radio waves are converted into power by an antenna such as a rectenna. Alternatively, kinetic energy due to vibration is converted into electric power by use of electromagnetic induction, inverse magnetostrictive vibration power generation, piezoelectric power generation, or electrostatic induction. The energy harvester 288 charges the capacitive element 287 in advance, and the power supply control unit 286 supplies power from the capacitive element 287 or the energy harvester 288 when the power supply is shut off.

In the auxiliary power supply unit 280 exemplified in c of the drawing, a secondary battery 289 is further added. The power supply control unit 286 charges the secondary battery 289 before the power supply is shut off, and supplies power from the secondary battery 289 when the power supply is shut off.

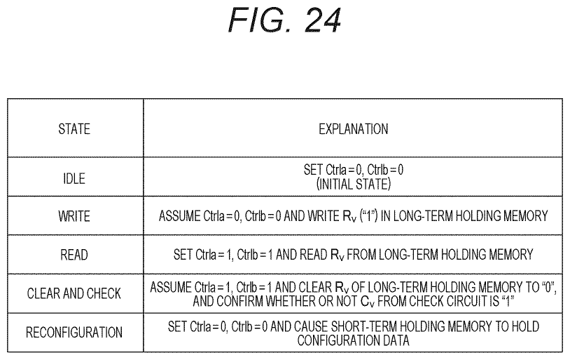

FIG. 24 is a diagram for explaining a state according to the second modification of the third embodiment of the present technology. Only portions different from the third embodiment will be described. In the idle state (that is, the initial state), the power supply shutoff recovery control unit 221 sets both the control signals Ctrla and Ctrlb to “0”. Also in the write state, the control signals Ctrla and Ctrlb are set to “0”.

Upon shifting to the read state, the power supply shutoff recovery control unit 221 sets both the control signals Ctrla and Ctrlb to “1”. Furthermore, also in the clear and check state, both the control signals Ctrla and Ctrlb are set to “1”. Upon shifting to the reconfiguration state, the power supply shutoff recovery control unit 221 sets both the control signals Ctrla and Ctrlb to “0”.

Note that, in the second modification of the third embodiment, the data holding times can be set in two stages instead of three or more stages. Furthermore, the second embodiment and the first modification of the third embodiment can also be applied to the second modification of the third embodiment.

As described above, according to the second modification of the third embodiment of the present technology, because the check circuit 260 compares the absolute value of the transient voltage with the reference voltage, it is possible to determine the presence or absence of data loss without performing the logical operation.

### [Third Modification]

In the third embodiment described above, the presence or absence of data loss is determined by reading the data from the short-term holding memory 240 and performing the logical operation, but the presence or absence of data loss can also be determined by a method other than the logical operation. The FPGA 200 according to a third modification of the third embodiment is different from that of the third embodiment in that the presence or absence of loss is determined from time information of a real time clock at the time when the power supply is shut off and when the power supply is recovered.

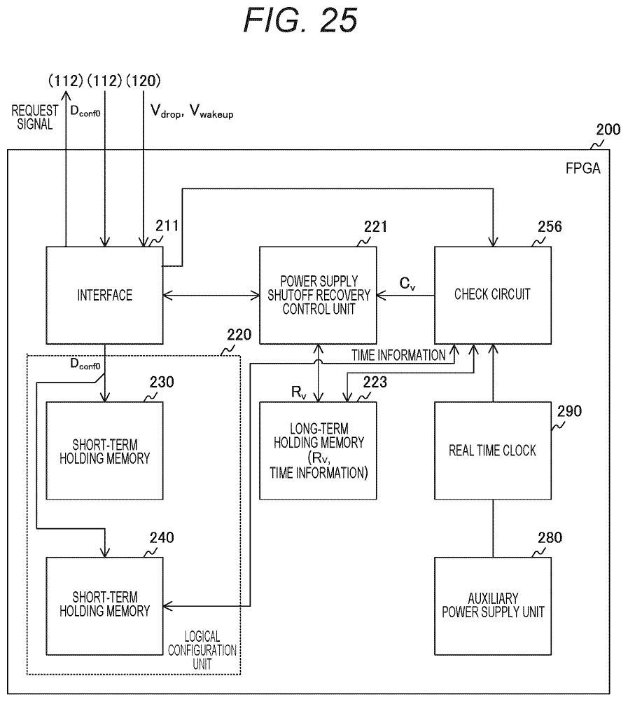

FIG. 25 is a block diagram illustrating a configuration example of the FPGA 200 according to the third modification of the third embodiment of the present technology. The FPGA 200 of the third modification of the third embodiment is different from that of the third embodiment in further including a real time clock 290 and the auxiliary power supply unit 280.

Furthermore, a check circuit 226 is provided instead of the check circuit 250. The power supply shutoff recovery control unit 221 and the check circuit 226 are implemented as a state machine.

The real time clock 290 clocks time and generates time information indicating a current time. Even during shutoff of the power supply, the real time clock 290 continues clocking by using the power from the auxiliary power supply unit 280. Any of the respective circuits exemplified in FIG. 23 is used as the circuit of the auxiliary power supply unit 280.

Furthermore, the short-term holding memory 240 further holds time information. In addition to Rv, the long-term holding memory 223 further holds the time information at the time of power shutoff.

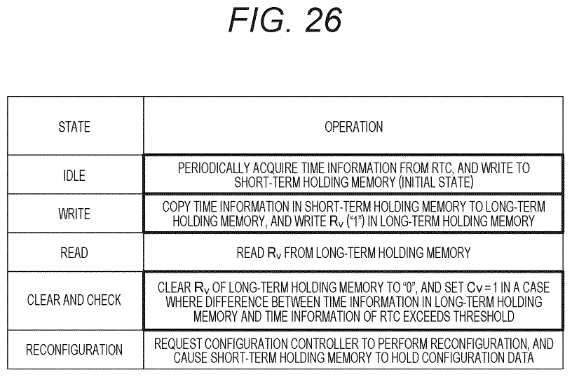

FIG. 26 is a diagram for explaining a state according to the third modification of the third embodiment of the present technology. A thick frame portion in the drawing indicates a portion different from that of the first embodiment. Only portions different from the first embodiment will be described.

Upon shifting to the idle state, the check circuit 226 periodically acquires time information from the real time clock 290, and writes the time information in the short-term holding memory 240.

Upon shifting to the write state, the check circuit 226 copies the time information in the short-term holding memory 240 to the long-term holding memory 223.

Then, upon shifting to the clear and check state, the check circuit 226 determines whether or not a difference between the time indicated by the time information in the long-term holding memory 223 and the time indicated by the time information of the real time clock 290 exceeds a predetermined threshold. A time equal to or more than the data holding time TIPI of the short-term holding memory 240 is set as the threshold. In a case where the difference is equal to or more than the threshold, the check circuit 226 determines that at least a part of the configuration data is lost and sets Cv to “1”.

As exemplified in the drawing, by obtaining the difference between the time information of the real time clock 290 at the time when the power supply is shut off and when the power supply is recovered, it is possible to determine the presence or absence of data loss without performing the logical operation.

Note that, in the third modification of the third embodiment, the data holding times can be set in two stages instead of three or more stages. Furthermore, the second embodiment and the first modification of the third embodiment can also be applied to the third modification of the third embodiment.

As described above, according to the third modification of the third embodiment of the present technology, because the check circuit 226 obtains the difference between the time information of the real time clock 290 at the time when the power supply is shut off and when the power supply is recovered, respectively, it is possible to determine the presence or absence of data loss without performing the logical operation.

### 4. Fourth Embodiment

In the first embodiment described above, the plurality of memories having different data holding times is disposed in the FPGA 200, but these memories can also be provided in a semiconductor integrated circuit other than the FPGA. An electronic device 100 according to a fourth embodiment is different from that of the first embodiment in that a plurality of memories having different data holding times is provided in an LSI.

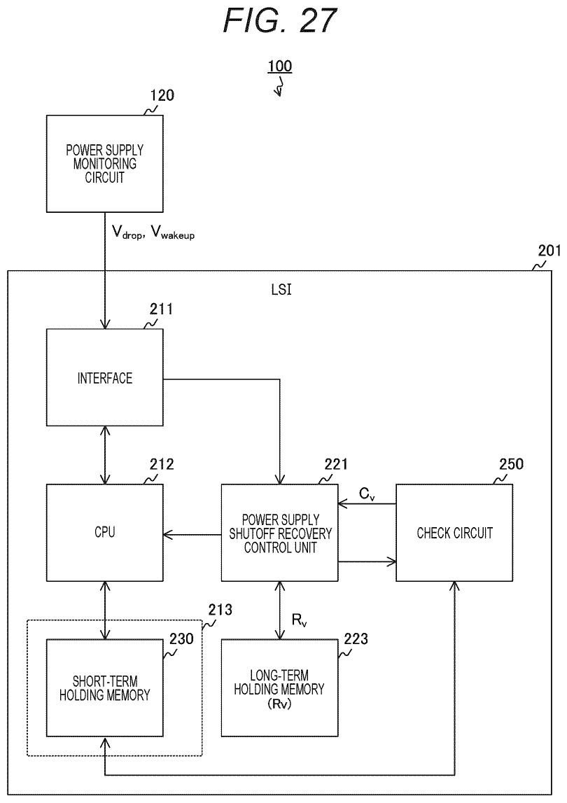

FIG. 27 is a block diagram illustrating a configuration example of the electronic device 100 according to the fourth embodiment of the present technology. The electronic device 100 of the fourth embodiment includes a power supply monitoring circuit 120 and an LSI 201. Note that the LSI 201 is an example of a semiconductor integrated circuit described in the claims.

In the LSI 201, an interface 211, a central processing unit (CPU) 212, a control register 213, a power supply shutoff recovery control unit 221, a long-term holding memory 223, and a check circuit 250 are disposed. A short-term holding memory 230 is provided in the control register 213. Note that the control register 213 is an example of a register described in the claims.

A module including the CPU 212 is controlled by configuration data held in the control register 213. The configuration data is held in the control register 213 by firmware described by using a Voratile variable. That is, the Voratile variable and the control register 213 are associated with each other by firmware. Here, a Voratile variable set value is written to the control register 213 by the firmware immediately after resetting. The long-term holding memory 223 stores Rv. Furthermore, although not illustrated in the drawing, the firmware is stored in the long-term holding memory 233 or the ROM directly connected to the CPU 212.

The configuration of the check circuit 250 according to the fourth embodiment is similar to that in the first embodiment. Furthermore, the power supply shutoff recovery control unit 221 according to the fourth embodiment functions as a state machine. Similarly to the first embodiment, also in the present embodiment, the power supply recovery unit 221 is implemented as dedicated hardware including a flip-flop or a latch constituted of a memory cell in the long-term holding memory 223 and a logical circuit.

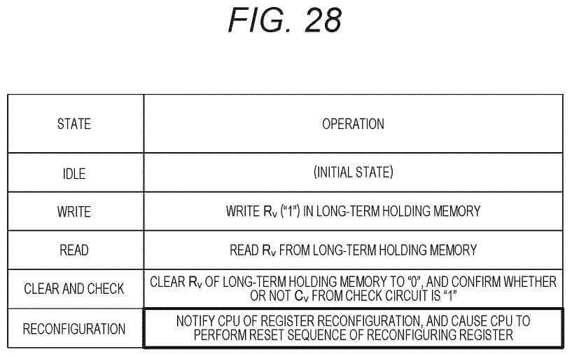

FIG. 28 is a diagram for explaining a state according to the fourth embodiment of the present technology. A thick frame portion in the drawing indicates a portion different from that of the first embodiment. Only this different portion will be described.

Upon shifting to the reconfiguration state, the power supply shutoff recovery control unit 221 notifies the CPU 212 that the control register 213 needs to be reconfigured. The CPU 212 reads the firmware from the ROM and performs the reset sequence of reconfiguring the control register 213. This firmware is written in the ROM from the beginning to cause the firmware to determine whether or not to reconfigure the control register according to the determination result of the power supply shutoff recovery control unit 221, and to reconfigure the control register as necessary. For example, in a case where Cv is “1” (that is, data is not lost), reconfiguration of the Voratile variable is skipped. On the other hand, in a case where Cv is “0” (that is, data is lost), the Voratile variable is reconfigured.

Note that the second embodiment can be applied to the fourth embodiment.

As described above, according to the fourth embodiment of the present technology, because the plurality of memories having different data holding times is provided in the LSI 201, it is possible to reduce the power consumption at the time of writing in the LSI 201 and the area thereof.

### [First Modification]

In the fourth embodiment described above, the data holding times of the memory are separately set in two stages, which are T_{LP} and T_{NV}, but the data holding times may be separately set in three or more stages. The LSI 201 of a first modification of the fourth embodiment is different from the first embodiment in that the short-term holding memory 230 and a short-term holding memory 240 having different data holding times are disposed in addition to the long-term holding memory 223.

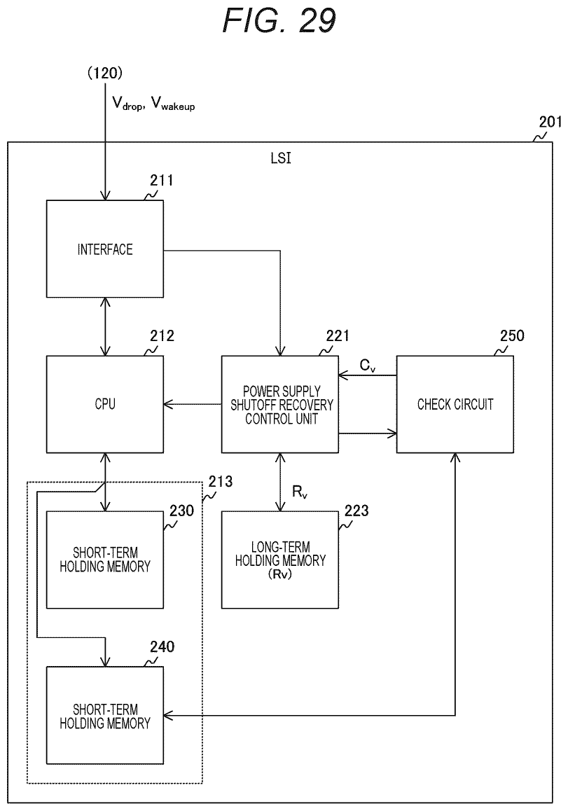

FIG. 29 is a block diagram illustrating a configuration example of the LSI 201 according to the first modification of the fourth embodiment of the present technology. The LSI 201 of the first modification of the fourth embodiment is different from that of the fourth embodiment in that the short-term holding memory 240 is further provided in the control register 213. The data holding times of the short-term holding memories 230 and 240 are different from each other.

Note that, although the data holding times are set in three stages, the data holding time may be set in four or more stages. In this case, K (K is an integer of 3 or more) pieces of the short-term holding memories having different data holding times are disposed.

The check circuit 250 determines the presence or absence of data loss by using the above-described method (i) or (ii). The power supply shutoff recovery control unit 221 performs the control of (iii) or (iv). At this time, the power supply shutoff recovery control unit 221 acquires an identification number k′ (k′ is an integer from 1 to K) allocated to a memory having the longest data holding time among the short-term holding memories to be reconfigured. It is assumed that as k′ becomes smaller, the corresponding data holding time becomes shorter. Then, the power supply shutoff recovery control unit 221 notifies the CPU 212 that it is necessary to reconfigure the short-term holding memory of k′ or less.

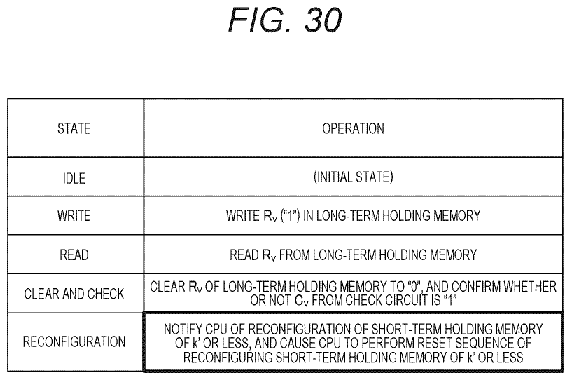

FIG. 30 is a diagram for explaining a state according to the first modification of the fourth embodiment of the present technology. A thick frame portion in the drawing indicates a portion different from that of the fourth embodiment. Only this different portion will be described.

Upon shifting to the reconfiguration state, the power supply shutoff recovery control unit 221 notifies the CPU 212 that the short-term holding memory of k′ or less needs to be reconfigured. The CPU 212 reads the firmware from the ROM and performs the reset sequence of reconfiguring the short-term holding memory of k′ or less.

Note that the second embodiment can be applied to the first modification of the fourth embodiment.

As described above, according to the first modification of the fourth embodiment of the present technology, because the short-term holding memories 230 and 240 having different data holding times are disposed, the number of memory cells to be checked can be reduced.

### [Second Modification]

In the fourth embodiment described above, the presence or absence of data loss is determined by reading the data from the short-term holding memory 240 and performing the logical operation, but the presence or absence of data loss can also be determined by a method other than the logical operation. The FPGA 200 according to a second modification of the fourth embodiment is different from that of the fourth embodiment in that presence or absence of data loss is determined by comparing an absolute value of a transient voltage of an LC resonance circuit with a reference voltage.

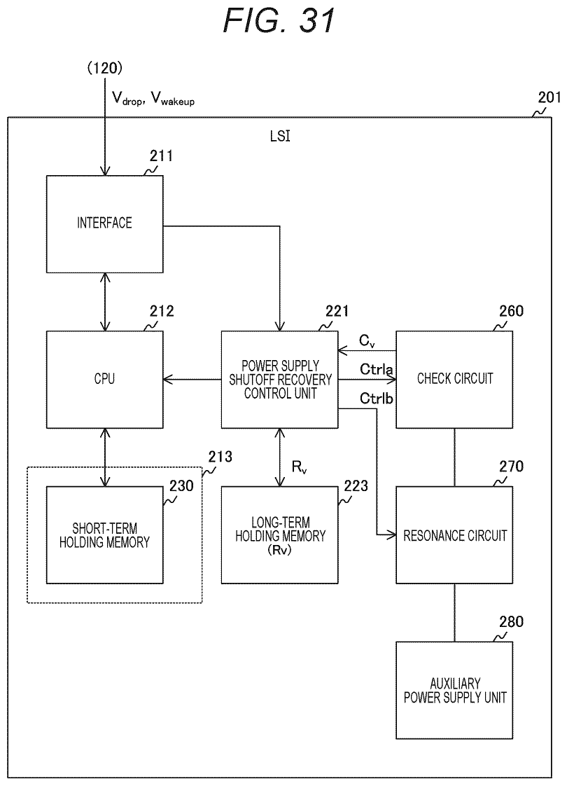

FIG. 31 is a block diagram illustrating a configuration example of the LSI 201 according to the second modification of the fourth embodiment of the present technology. The LSI 201 of the second modification of the fourth embodiment includes a check circuit 260, a resonance circuit 270, and an auxiliary power supply unit 280 instead of the check circuit 250. The circuit configurations of these circuits are similar to those exemplified in FIGS. 22 and 23.

Furthermore, each state of the state machine according to the second modification of the fourth embodiment of the present technology is similar to that exemplified in FIG. 28.

Note that the first modification of the fourth embodiment in which the plurality of short-term holding memories having different data holding times is disposed can also be applied to the second modification of the fourth embodiment. In this case, each state of the state machine is as exemplified in FIG. 30.

Furthermore, the second embodiment can also be applied to the second modification of the fourth embodiment.

As described above, according to the second modification of the fourth embodiment of the present technology, because the check circuit 260 compares the absolute value of the transient voltage with the reference voltage, it is possible to determine the presence or absence of data loss without performing the logical operation.

### [Third Modification]

In the fourth embodiment described above, the presence or absence of data loss is determined by reading the data from the short-term holding memory 240 and performing the logical operation, but the presence or absence of data loss can also be determined by a method other than the logical operation. The FPGA 200 according to a third modification of the fourth embodiment is different from that of the fourth embodiment in that the presence or absence of loss is determined from time information of a real time clock at the time when the power supply is shut off and when the power supply is recovered.

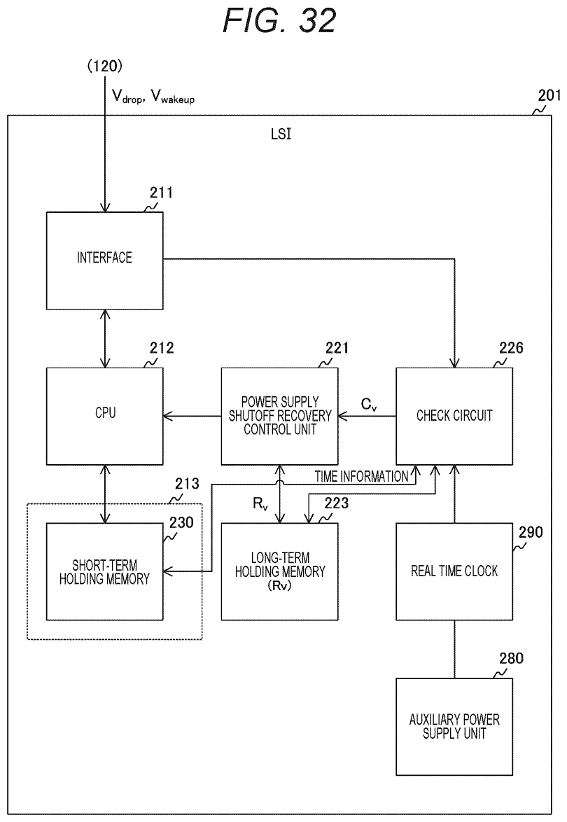

FIG. 32 is a block diagram illustrating a configuration example of the LSI 201 according to the third modification of the fourth embodiment of the present technology. The LSI 201 according to the third modification of the fourth embodiment is different from that of the fourth embodiment in including a check circuit 226, a real time clock 290, and the auxiliary power supply unit 280 instead of the check circuit 250. The circuit configurations of these circuits are similar to those illustrated in FIG. 25.

Furthermore, each state of the state machine according to the third modification of the fourth embodiment of the present technology is similar to that exemplified in FIG. 28.

Note that the first modification of the fourth embodiment in which the plurality of short-term holding memories having different data holding times is disposed can also be applied to the third modification of the fourth embodiment. In this case, each state of the state machine is as exemplified in FIG. 30.

Furthermore, the second embodiment can also be applied to the third modification of the fourth embodiment.

As described above, according to the third modification of the fourth embodiment of the present technology, because the check circuit 226 obtains the difference between the time information of the real time clock 290 at the time when the power supply is shut off and when the power supply is recovered, respectively, it is possible to determine the presence or absence of data loss without performing the logical operation.

### 5. Application Example to Mobile Body

The technology according to the present disclosure (the present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a ship, or a robot.

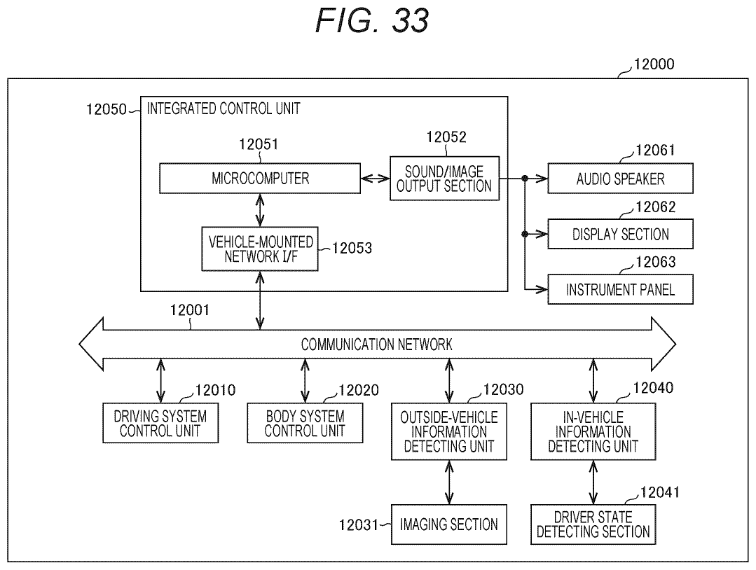

FIG. 33 is a block diagram illustrating a schematic configuration example of a vehicle control system, which is an example of a mobile body control system to which the technology according to the present disclosure can be applied.

The vehicle control system 12000 includes a plurality of electronic control units connected to each other via a communication network 12001. In the example illustrated in FIG. 33, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information on the outside of the vehicle, the information being obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 33, an audio speaker 12061, a display section 12062, and an instrument panel 12063 are exemplified as the output device. The display section 12062 may, for example, include at least one of an on-board display and a head-up display.

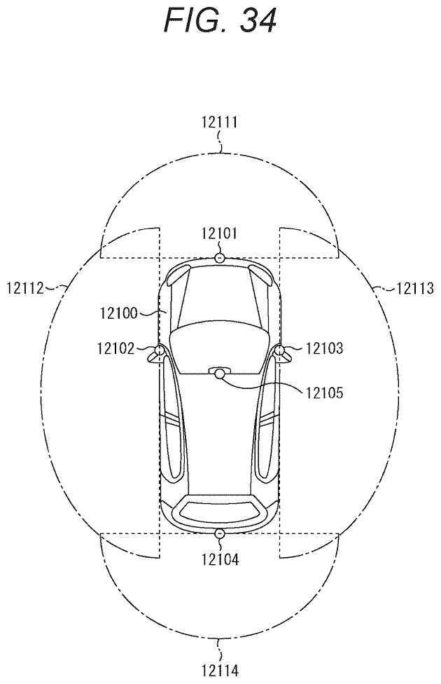

FIG. 34 is a diagram illustrating an example of the installation position of the imaging section 12031.

In FIG. 34, the imaging section 12031 includes imaging sections 12101, 12102, 12103, 12104, and 12105.

The imaging sections 12101, 12102, 12103, 12104, and 12105 are, for example, provided at positions such as a front nose, sideview mirrors, a rear bumper, and a back door of the vehicle 12100, and on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors mainly obtain an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 34 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the configurations described above. For example, the electronic device 100 in FIG. 1 can be applied to the imaging section 12031. By applying the technology according to the present disclosure to the imaging section 12031, the power consumption can be reduced.

Note that, the above embodiments show examples for embodying the present technology, and matters in the embodiments and matters specifying the invention in the claims have correspondence relationships. Similarly, the matters specifying the invention in the claims and matters with the same names in the embodiments of the present technology have correspondence relationships. However, the present technology is not limited to the embodiments and can be embodied by making various modifications to the embodiments without departing from the gist thereof.

Note that effects described in the present description are merely examples and are not limited, and other effects may be provided.

Note that the present technology may also have the following configurations.
(1) A semiconductor integrated circuit including:
a short-term holding memory that has a data holding time shorter than a predetermined time and holds predetermined configuration data; and
a long-term holding memory that has a data holding time being the predetermined time and holds specific data indicating whether or not a power supply voltage is recovered after dropping to a value lower than a constant voltage.
(2) The semiconductor integrated circuit according to (1) described above, in which
the short-term holding memory is one of a magnetoresistive random access memory (MRAM) and a non-volatile static random access memory (SRAM), and the long-term holding memory is also one of the MRAM and the SRAM.
(3) The semiconductor integrated circuit according to (1) described above, in which
each of the short-term holding memory and the long-term holding memory includes a memory cell disposed at an intersection of a bit line and a word line.
(4) The semiconductor integrated circuit according to any one of (1) to (3) described above, further including a check circuit that determines whether or not at least a part of the configuration data is lost and outputs a determination result.
(5) The semiconductor integrated circuit according to (4) described above, in which
the short-term holding memory includes a plurality of memory cells that holds the same value, and
the check circuit determines whether or not all the held values of the plurality of memory cells coincide with each other.
(6) The semiconductor integrated circuit according to (4) described above, in which
the short-term holding memory includes a plurality of first memory cells that holds a first logical value and a plurality of second memory cells that holds a second logical value different from the first logical value, and
the check circuit determines whether or not all the held values of the plurality of first memory cells coincide with each other and all the held values of the plurality of second memory cells coincide with each other.
(7) The semiconductor integrated circuit according to any one of (4) to (6) described above, further including
a power supply shutoff recovery control unit that transits to: a write state in which the specific data having a value different from an initial value is held in the long-term holding memory in a case where the power supply voltage drops to a value lower than the constant voltage; a read state in which the specific data is read from the long-term holding memory in a case where the power supply voltage recovers to a value higher than the constant voltage; a check state in which the determination result is acquired in a case where the specific data that is read is not the initial value; and a reconfiguration state in which predetermined initial configuration data is held in the short-term holding memory as new configuration data in a case where at least a part of the configuration data is lost.
(8) The semiconductor integrated circuit according to (7) described above, in which,
in a case where at least a part of the configuration data is lost, the power supply shutoff recovery control unit causes the short-term holding memory to hold the initial configuration data read from a read only memory as new configuration data.
(9) The semiconductor integrated circuit according to (7) described above, in which
the long-term holding memory further holds the initial configuration data, and
the power supply shutoff recovery control unit causes the short-term holding memory to hold the initial configuration data read from the long-term holding memory as new configuration data in a case where at least a part of the configuration data is lost.
(10) The semiconductor integrated circuit according to (1) described above, further including a check circuit that determines whether or not at least a part of the configuration data is lost and outputs a determination result, and an auxiliary power supply unit that supplies a predetermined auxiliary voltage when the power supply voltage is shut off.
(11) The semiconductor integrated circuit according to (10) described above, in which the auxiliary power supply unit includes a diode and a capacitive element connected in series to the power supply voltage.
(12) The semiconductor integrated circuit according to (11) described above, in which the auxiliary power supply unit further includes a primary battery that supplies the auxiliary voltage.
(13) The semiconductor integrated circuit according to (11) described above, in which the auxiliary power supply unit further includes an energy harvester that performs energy harvesting.
(14) The semiconductor integrated circuit according to (13) described above, in which
the auxiliary power supply unit further includes a secondary battery that is charged with power from the energy harvester and is discharged when the power supply voltage is shut off.
(15) The semiconductor integrated circuit according to any one of (10) to (14) described above, further including
a resonance circuit that generates a transient voltage that fluctuates with a lapse of time when the auxiliary voltage is supplied, in which
the check circuit compares an absolute value of the transient voltage with a predetermined reference voltage and outputs a result of the comparison as the determination result.
(16) The semiconductor output circuit according to any one of (10) to (14) described above, further including
a real time clock that generates predetermined time information, in which
the check circuit causes the long-term holding memory to hold time information when the power supply voltage is shut off, and determine whether or not a difference between a time indicated by the held time information and a time indicated by newly generated time information exceeds a predetermined threshold when the power supply voltage is recovered.
(17) The semiconductor integrated circuit according to any one of (1) to (16) described above, in which the short-term holding memory includes first and second short-term holding memories having different data holding times.
(18) The semiconductor integrated circuit according to any one of (1) to (17) described above, in which
the semiconductor integrated circuit is a field-programmable gate array (FPGA),
the configuration data includes wire connection information of a logical block and connection information of a switch block,
the short-term holding memory is disposed in the logical block and the switch block, and
the long-term holding memory is disposed in the logical block.
(19) The semiconductor integrated circuit according to any one of (1) to (18) described above, in which
the semiconductor integrated circuit is an LSI, and
the short-term holding memory is disposed in a predetermined register.
(20) An electronic device including:
a semiconductor integrated circuit including a short-term holding memory that has a data holding time shorter than a predetermined time and holds predetermined configuration data and a long-term holding memory that has a data holding time longer than the predetermined time and holds specific data indicating whether or not a power supply voltage is recovered after dropping to a value lower than a constant voltage; and
a power supply monitoring circuit that supplies a predetermined detection signal to the semiconductor integrated circuit in a case where it is detected that the power supply voltage is dropped to a value lower than the constant voltage.
(21) The electronic device according to (20) described above, further including:
a read only memory that holds initial configuration data; and
a configuration controller that reads the initial configuration data from the read only memory and supplies the initial configuration data to the semiconductor integrated circuit.

### REFERENCE SIGNS LIST

100 Electronic device
111 Configuration ROM
112, 224 Configuration controller
120 Power supply monitoring circuit
121 to 123 Resistor
124 Reset switch
125 Power supply monitoring IC
200 FPGA
201 LSI
211 Interface
212 CPU
213 Control register
220 Logical configuration unit
221 Power supply shutoff recovery control unit
223 Long-term holding memory
226, 250, 260 Check circuit
230, 240 Short-term holding memory
231 to 234, 331, 341, 401 to 406, 441 to 446, 451 to 458 Memory cell
251, 254 Logical product (AND) gate
252, 253 Exclusive logical sum (XOR) gate
255 Negative logical sum (NOR) gate
256, 257 Read/write control unit
261 Comparison circuit
262 Absolute value circuit
263 Reference voltage generation circuit
264, 275, 276, 321 to 326, 411 to 414 nMOS transistor
271 to 274, 283, 415 to 418 pMOS transistor
270 resonance circuit
277, 282, 287 Capacitive element
278 Inductive element
280 Auxiliary power supply unit
281, 284 Diode
285 Primary battery
286 Power supply control unit
288 Energy harvester
289 Secondary battery
290 Real time clock
310 Switch block
311 to 313 Bit line
314 to 316 Word line
320, 327 Switch circuit
330, 340 Logical block
332, 342 Look-up table
421 to 425 Inverter
431, 432 MTJ element
12031 Imaging section claims

1. A semiconductor integrated circuit comprising:
a short-term holding memory that has a data holding time shorter than a predetermined time and holds predetermined configuration data; and
a long-term holding memory that has a data holding time being the predetermined time and holds specific data indicating whether or not a power supply voltage is recovered after dropping to a value lower than a constant voltage.

2. The semiconductor integrated circuit according to claim 1, wherein
the short-term holding memory is one of a magnetoresistive random access memory (MRAM) and a non-volatile static random access memory (SRAM), and the long-term holding memory is also one of the MRAM and the SRAM.

3. The semiconductor integrated circuit according to claim 1, wherein
each of the short-term holding memory and the long-term holding memory includes a memory cell disposed at an intersection of a bit line and a word line.

4. The semiconductor integrated circuit according to claim 1, further comprising
a check circuit that determines whether or not at least a part of the configuration data is lost and outputs a determination result.

5. The semiconductor integrated circuit according to claim 4, wherein
the short-term holding memory includes a plurality of memory cells that holds a same value, and
the check circuit determines whether or not all held values of the plurality of memory cells coincide with each other.

6. The semiconductor integrated circuit according to claim 4, wherein
the short-term holding memory includes a plurality of first memory cells that holds a first logical value and a plurality of second memory cells that holds a second logical value different from the first logical value, and
the check circuit determines whether or not all held values of the plurality of first memory cells coincide with each other and all the held values of the plurality of second memory cells coincide with each other.

7. The semiconductor integrated circuit according to claim 4, further comprising
a power supply shutoff recovery control unit that transits to: a write state in which the specific data having a value different from an initial value is held in the long-term holding memory in a case where the power supply voltage drops to a value lower than the constant voltage; a read state in which the specific data is read from the long-term holding memory in a case where the power supply voltage recovers to a value higher than the constant voltage; a check state in which the determination result is acquired in a case where the specific data that is read is not the initial value; and a reconfiguration state in which predetermined initial configuration data is held in the short-term holding memory as new configuration data in a case where at least a part of the configuration data is lost.

8. The semiconductor integrated circuit according to claim 7, wherein,
in a case where at least a part of the configuration data is lost, the power supply shutoff recovery control unit causes the short-term holding memory to hold the initial configuration data read from a read only memory as new configuration data.

9. The semiconductor integrated circuit according to claim 7, wherein
the long-term holding memory further holds the initial configuration data, and
the power supply shutoff recovery control unit causes the short-term holding memory to hold the initial configuration data read from the long-term holding memory as new configuration data in a case where at least a part of the configuration data is lost.

10. The semiconductor integrated circuit according to claim 1, further comprising:
a check circuit that determines whether or not at least a part of the configuration data is lost and outputs a determination result; and
an auxiliary power supply unit that supplies a predetermined auxiliary voltage when the power supply voltage is shut off.

11. The semiconductor integrated circuit according to claim 10, wherein the auxiliary power supply unit includes a diode and a capacitive element connected in series to the power supply voltage.

12. The semiconductor integrated circuit according to claim 11, wherein the auxiliary power supply unit further includes a primary battery that supplies the auxiliary voltage.

13. The semiconductor integrated circuit according to claim 11, wherein the auxiliary power supply unit further includes an energy harvester that performs energy harvesting.

14. The semiconductor integrated circuit according to claim 13 described above, wherein
the auxiliary power supply unit further includes a secondary battery that is charged with power from the energy harvester and is discharged when the power supply voltage is shut off.

15. The semiconductor integrated circuit according to claim 10, further comprising
a resonance circuit that generates a transient voltage that fluctuates with a lapse of time when the auxiliary voltage is supplied, wherein
the check circuit compares an absolute value of the transient voltage with a predetermined reference voltage and outputs a result of the comparison as the determination result.

16. The semiconductor output circuit according to claim 10, further comprising
a real time clock that generates predetermined time information, wherein
the check circuit causes the long-term holding memory to hold time information when the power supply voltage is shut off, and determine whether or not a difference between a time indicated by the held time information and a time indicated by newly generated time information exceeds a predetermined threshold when the power supply voltage is recovered.

17. The semiconductor integrated circuit according to claim 1, wherein the short-term holding memory includes first and second short-term holding memories having different data holding times.

18. The semiconductor integrated circuit according to claim 1, wherein
the semiconductor integrated circuit is a field-programmable gate array (FPGA),
the configuration data includes wire connection information of a logical block and connection information of a switch block,
the short-term holding memory is disposed in the logical block and the switch block, and
the long-term holding memory is disposed in the logical block.

19. The semiconductor integrated circuit according to claim 1, wherein
the semiconductor integrated circuit is a large scale integration (LSI), and
the short-term holding memory is disposed in a predetermined register.

20. An electronic device comprising:
a semiconductor integrated circuit comprising a short-term holding memory that has a data holding time shorter than a predetermined time and holds predetermined configuration data and a long-term holding memory that has a data holding time longer than the predetermined time and holds specific data indicating whether or not a power supply voltage is recovered after dropping to a value lower than a constant voltage; and
a power supply monitoring circuit that supplies a predetermined detection signal to the semiconductor integrated circuit in a case where it is detected that the power supply voltage is dropped to a value lower than the constant voltage.

21. The electronic device according to claim 20, further comprising:
a read only memory that holds initial configuration data; and
a configuration controller that reads the initial configuration data from the read only memory and supplies the initial configuration data to the semiconductor integrated circuit.
